(19) United States
(12) Patent Application Publication
(10) Pub. No.: US 2026/0358363 A1
(43) Pub. Date: Nov. 12, 2026

(54) HIGH SPEED MAGNETIC ANGLE SENSOR

(71) Applicant: Spindrift Innovations, LLC, Redwood City, CA (US)

(72) Inventors: Robert D. Zucker, Half Moon Bay, CA (US); Robert P. Weber, Redwood City, CA (US)

(21) Appl. No.: 19/578,722

(22) Filed: Mar. 25, 2026

Related U.S. Application Data
(60) Provisional application No. 63/777,530, filed on Mar. 25, 2025.

(51) Int. Cl. G01P 3/44; G01D 5/14

(52) U.S. Cl. CPC G01P 3/44; G01D 5/14

(57) ABSTRACT

A magnetic angle sensor extracts the orientation of a magnetic field intersecting a plane containing two orthogonal sensors with a common centroid. The sensor uses a digitally driven pair of multiplying DACs to respectively modulate signals from a pair of magnetic sensor bridges. A reference oscillator is used as a timing reference. The modulated signals are combined to start and stop a counter whose held value represents the field angle. This approach allows for fast results with low latency. Flexible operational low power and incremental acquisition modes allow for accelerated results while reducing power. The initial angle and velocity are arbitrary since acquisition is independent of rotational direction and initial angle. Near zero latency operation is supported. High magnetic rotation rates support the fastest mechanical systems.

### CROSS-REFERENCE TO RELATED APPLICATIONS

This application claims priority to U.S. Provisional Patent Application Ser. No. 63/777,530, filed on Mar. 25, 2025, and titled “High Speed Magnetic Angle Sensor Systems With Low Latency And With Low Power Consumption” which is hereby incorporated, in its entirety, by reference. In the event of any inconsistency between this application and the documents incorporated by reference, then this application shall control.

### BACKGROUND

A broad variety of magnetic angle sensor systems are known to exist in the marketplace. These sensor systems are implemented using various current sensor technologies (e.g., Hall, AMR, GMR, and TMR sensors, but not limited to this list) and various architectures. These implementations all have in common a configuration in which two collocated substantially orthogonal sensors are placed near a rotating magnet. The magnet is oriented and positioned such that as it rotates, its North & South poles are exchanged every 180 degrees of rotation. Additionally, the axis of rotation is substantially orthogonal to the plane in which the sensor pair resides, and its axis is either substantially coincident with the center of the sensor pair, or it may be offset from the center of the sensor pair. A simplified diagram of the magnet and the magnetic sensors is illustrated in FIG. 1, representing the ideal case in which the magnet and the sensor are coincident. Equation 1 indicates how the angle α is recovered from the sine and cosine signals in the ideal geometric relationship.

α=tan (cos α/sin α) Equation 1

The solid black circle on the left side of FIG. 1 represents the location of the spinning magnet and the coincident location of the magnetic sensor. The pair of sensors typically are oriented (substantially) 90 degrees apart resulting in a complementary sine and cosine wave output from the sensor pair.

An example magnetic angle sensor is described in U.S. Patent Publication 2023/0134728, and the architecture described is herein referred to as the “'728 architecture.” The architectural diagram of the '728 architecture shown in FIG. 4, and an equivalent diagram of FIG. 5, contains a functional error: the actual value (binary code) of the output of the counter is not representative of a degrees, but it is actually representative of (360−α) degrees as illustrated in the timing diagram in FIG. 6 in which the interval from the START signal to the STOP signal is 270 degrees when α is 90 degrees. This incorrect angle extraction occurs because the '728 architecture is based on Equation 2B: cos α*cos ft−sin α*sin ft=cos(α+ft) which has a STOP signal which is delayed with respect to the START signal. This error is resolved by basing the architecture on Equation 2A: sin α*cos ft−cos α*sin ft=sin(α−ft) which correctly positions the STOP signal to be delayed with respect to the START signal. An alternative remedy to the angle error issue identified in the '728 is implemented by changing the angle counter from the standard up-counter to a down-counter.

The utilization of a differencing amplifier in FIG. 4 (500) in the '728, also indicated in FIG. 5 (labeled as Av=1), introduces several undesirable issues. It must be a high-speed amplifier compared to the input amplifier and thus requires large amount of power. It can add undesirable distortions to the waveform which will affect timing. It adds a delay into the STOP signal path which induces a timing error. The utilization of the differencing amplifier makes it impossible for the signal paths to the output of the START and the STOP comparators to have equal delays, inducing a systematic error into the angle measurement.

### SUMMARY

Only the zero crossing events of the sinusoidal waveforms need to be accurately preserved to extract the magnetic angle from the generated signals. Based on this observation a differencing amplifier used in other sensors can be replaced by the STOP comparator, which is processing a difference between two signals rather than simply comparing a single signal to the ground reference. This allows the START and STOP paths to have equalized delays. In some implementations this can be realized as a virtualization of the differential amplifier. Such a sensor has reduced latency, increased speed, and lower power consumption.

Some implementations use internal digital sine and digital cosine wave generators that operate at a substantially higher frequency than the sine and cosine waves produced by the pair of sensors. These four waveforms are effectively combined through a multiplication (modulation) and differencing process in the analog voltage domain to control a digital counter that produces a count which is proportional to the angle of the magnetic field experienced by the sensor pair.

The trigonometric identity (Equation 2A) can be used to electronically calculate the angle of the magnetic field, but other trigonometric equivalencies to Equation 2A listed below can be used in some implementations (Equations 2B, 2C, 2D, 2E, and 2F).

sin α*cos ft−cos α*sin ft=sin(α−ft) Equation 2A

Other equivalent equations that may be utilized.

cos α*cos ft−sin α*sin ft=cos(α+ft) Equation 2B

cos α*sin ft−sin α*cos ft=sin(ft−α) Equation 2C

cos α*cos ft−sin α*sin ft=cos(ft−α) Equation 2D

sin α*cos ft+cos α*sin ft=sin(α+ft) Equation 2E

cos α*cos ft+sin α*sin ft=cos(α−ft) Equation 2F

Thus, a circuit for measuring an angle of a magnetic field is designed based on a principle that only the zero crossing events of the sinusoidal waveforms need to be accurately preserved to extract the magnetic angle. Based on this observation, a differencing amplifier used in other sensors can be replaced by a STOP comparator, which processes a difference between two signals rather than simply comparing a single signal to a ground reference. These two signals are directly connected the two inputs to the output comparator, which removes unwanted delays in the signal path, enables improved and higher speed operation, and allows the START and STOP paths to have equalized delays.

Accordingly, in one aspect, a circuit for measuring the angle and angular velocity of a magnetic field imposed upon a pair of magnetic sensors includes a first electronic circuit having a first multiplying digital to analog converter (DAC) with a first reference input, a first digital input receiving a first waveform at a substantially higher frequency (f) than a rotational frequency of the magnetic field, and a first DAC output. The first electronic circuit also includes a first programmable gain differential to single-ended amplifier having a first input connected to receive a first electronic signal from a first magnetic sensor, and a first amplifier output connected to the first reference input. A second electronic circuit includes a second multiplying DAC with corresponding inputs and outputs, and a second programmable gain differential to single-ended amplifier having a second input connected to receive a second electronic signal from a second magnetic sensor, and a second amplifier output connected to the second reference input. A first zero-crossing detection circuit comprises a first comparator having an input connected to receive a signal based on the first DAC output, and configured to compare the signal based on the first DAC signal to a reference signal to produce a first zero-crossing signal having an edge when the first DAC output crosses the reference signal. A second zero-crossing detection circuit comprises a second comparator, having a substantially similar delay as the first comparator, connected to receive a first signal based on the first DAC output and a second signal based on the second DAC output, and configured to compare the first signal to the second signal to produce a second zero-crossing signal having an edge when the first signal and second signal cross. A digital counter, clocked by a clock signal having a clock frequency greater than the frequency (f), has a first input connected to receive the first zero-crossing signal and a second input connected to receive the second zero-crossing signal, the digital counter configured to start and stop counting based on the first zero-crossing signal and the second zero-crossing signal, the digital counter having a counter output indicative of a measurement of an angle of an external magnetic field imposed upon the sensors.

In one aspect, a circuit for measuring the angle and angular velocity of a magnetic field includes a first magnetic sensor at a first physical location at a first fixed orientation such that the first magnetic sensor generates a first electronic signal representing a sine of an angle of the magnetic field, and a second magnetic sensor at a second physical location in proximity to the first physical location and having a second fixed orientation orthogonal to the first fixed orientation such that the second magnetic sensor generates a second electronic signal representing a cosine of the angle of the magnetic field. The circuit further includes first and second electronic circuits with multiplying DACs and programmable gain differential to single-ended amplifiers, first and second zero-crossing detection circuits with comparators having substantially similar delays, and a digital counter configured to start and stop counting based on the zero-crossing signals to provide a counter output indicative of the magnetic field angle.

In one aspect, a circuit for measuring the angle and angular velocity of a magnetic field includes means for multiplying a first electrical signal based on an output of a first magnetic sensor with a first waveform at a substantially higher frequency (f) than a rotational frequency of the magnetic field to provide a first output, and means for multiplying a second electrical signal based on an output of a second magnetic sensor with a second waveform at the frequency (f) to provide a second output. The circuit includes first and second zero-crossing detection circuits with comparators having substantially similar delays, and a digital counter configured to start and stop counting based on the zero-crossing signals to provide a measurement of the magnetic field angle.

Any of the foregoing can include one or more of the following features. The first waveform and the second waveform are trigonometric waveforms. The measurement of the angle may comprise a value indicative of the angle or a complement of the angle according to a trigonometric function selected from the group comprising: sin α cos ft−cos α sin ft=sin(α−ft), cos α cos ft−sin α sin ft=cos(α+ft), cos α sin ft−sin α cos ft=sin(ft−α), cos α cos ft−sin α sin ft=cos(ft−α), sin α cos ft+cos α sin ft=sin(α+ft), or cos α cos ft+sin α sin ft=cos(α−ft).

Any of the foregoing can include one or more of the following features. The reference signal may comprise a fixed reference signal. The reference signal may comprise an inverse of the signal based on the first DAC signal.

Any of the foregoing can include one or more of the following features. The circuit may include a first first-order filter connected to receive the first DAC output to produce the signal based on the first DAC output, and a second first-order filter connected to receive the second DAC output to produce the signal based on the second DAC output. The circuit may further comprise a digital waveform generator configured to generate the first waveform and the second waveform.

Any of the foregoing can include one or more of the following features. The first and second multiplying digital to analog converters may be configured to operate only in a temporal vicinity of zero crossings. The digital counter may operate in a count-up mode. The digital counter may operate in a count-down mode. The circuit may be configured to operate in an incremental mode wherein temporal sections of the first waveform and the second waveform not in a temporal vicinity of zero crossings are eliminated. The circuit may be configured to disable analog signal paths when the sections of the first and second waveforms are not in the temporal vicinity of zero crossings. The circuit may be configured to repetitively trace through the counter values near the last count value.

Any of the foregoing can include one or more of the following features. The first comparator and the second comparator may be chopper stabilized. The first comparator and the second comparator may be chopper stabilized with chopping toggling on alternate angle acquisition cycles. The first differential amplifier and the second differential amplifier may be chopper stabilized.

There are several variations of such a circuit which can be implemented. For example, a single data rate count-up method uses up-counting angle extraction, which only utilizes the rising edges of START and STOP comparators. The extraction of angles is a continuous process in which an angle is periodically rendered.

As another example, a double data rate count-up method uses a modification to the circuit in which both the rising and falling edges of the START and STOP comparators are utilized to extract the angle. However, in this implementation, there are two extractions of the angle occurring in each operational cycle. These extractions occur 180 degrees apart from each other. The extraction of angle pairs can be a continuous process in which a pair of angles is periodically rendered. This method is illustrated in the architecture illustrated in FIG. 24.

As another example, virtualized rendering of the START event uses a circuit in which the START events are virtualized and averaged as a value of a cyclical counter and no longer are extracted in every operating cycle. A stored and averaged value is maintained and only gets refreshed frequently enough to account for thermal variations. In this mode, a single angle is extracted in each operational cycle.

As another example, double data rate with virtualized rendering of the START Events uses virtualizations of the START events, but by using both rising and falling edges two extractions of the angle may occur in each cycle.

As another example, pulsed power operation involves only enabling the AXE previous to expected START and STOP events to reduce power consumption.

As another example, partial cycle rendering reduced latency by manipulating a cyclical counter to only count out or “trace over” temporal regions in which positive zero crossing events occur. In this implementation a circuit is continuously operational, but the counter is initially stepping through the numbers that are prior to the START event and thus capture the START event. Subsequently, the counter jumps to a count that is prior to the count corresponding to the last STOP and thus captures a STOP event. This sequence can be repeated indefinitely. The numerical values of each START-STOP pair are differenced to render the angle. This sequence can repeat indefinitely producing an angle for each counter pair. A settling time margining can be added to each START and STOP acquisition to ensure that all analog circuits in the signal path have fully settled after being enabled. Optionally, the analog circuits can be all continuously enabled, in which case the counter jumps to a value that is prior to the last START and then the last STOP, with a timing margin allowing for the analog circuits to settle. The rate at which an angle is rendered may be one tenth of the rendering time of other implementations. To keep all rendering times uniform, a variable non-operational delay time may be added to each operational cycle. Thus, each cycle contains a START duration, a STOP duration, and a NOP (non-operational) duration.

As another example, partial cycle rendering with virtualized STARTs includes a circuit in which typical cycle, only a STOP is rendered. The START value is derived from an intermittent running average of START measurements are only updated enough to account for thermal drift. In this implementation, an additional cyclical counter, lookup table, and sin(ft) signal chain might optionally be added to extract START event measurements in parallel with STOP event measurements. These added components are much smaller than the components utilized to operate the STOP event measurements. This reduced size is due to the fact that while STOP events can occur at any arbitrary value of the cyclical counter, START events always occur near the beginning of each cycle and only a small range of counts is required to measure a START. To produce START events, only a small portion of a full cycle is required to be generated, and the value of this sub-count is always identical.

In some implementations, the circuit can use lower power comparators while trimming the comparator and the filter delays. Additionally, delays created in the digital domain by the multiplying DACs are predictable and may be accurately considered in the system since they are directly linked to the system clock frequency.

In some implementations, a single stage RC filter can be used. Such a filter settles much more quickly, adds negligible latency to the first angle rendering, and has some flexibility (less sensitivity) to the frequency of the reference oscillator. Thus, such an implementation allows for a system in which the reference oscillators may be arbitrability paused and even shifted in their phases. This flexibility allows for a higher update rate than a conventional continuously operating oscillator.

### BRIEF DESCRIPTION OF THE DRAWINGS

FIG. 1: Idealized diagram of sine and cosine magnetic sensors referencing Equation 1.

FIG. 2: Architecture of an angle extraction system using the trigonometric identity of Equation 2A: sin α*cos ft−cos α*sin ft=sin(α−ft).

FIG. 3: Timing diagram for architecture in FIG. 2 indicating the relationship between the signals driving the START and STOP comparators.

FIG. 4: Architectural diagram from prior art patent application US20230134728.

FIG. 5: Redrawing of prior art architecture from FIG. 4 for the purposes of clarity. Prior art implements the trigonometric identity of EQ2B: (cos α*cos ft)−(sin α*sin ft)=cos(α+ft).

FIG. 6: Timing diagram of the relationship between the signals driving the START and STOP comparators in FIG. 5 and FIG. 15. The measured angle α is 90 degrees.

FIG. 7: Method of eliminating the Differential amplifier from FIG. 4 and FIG. 5 by recognizing an equivalent circuit having a single comparator. This method is applied to all implementations herein.

FIG. 8: Architectural Diagram of the Double Data Rate Method as applied to Equation 2A. It is a variation of the Architecture in FIG. 2.

FIG. 9: Waveform Timing Diagram of the Double Data Rate Method Architecture in FIG. 8 when a=90 degrees.

FIG. 10: Enhancement of the Architecture of FIG. 2 which supports Virtualized START pulses.

FIG. 11: Enhancement of the Architecture of FIG. 10 which supports Power Savings by disabling Analog Power between all STARTs and STOPs. Power is only enabled based on the location of previous STARTs and STOPs. Analog Power is immediately disable after each START or STOP is detected.

FIG. 12: Waveform Timing Diagram for the operation of the architecture in FIG. 10 which shows the relationship between STARTs, STOPs, and dynamic analog power enabling which saves power.

FIG. 13: Further Enhancement of the Architecture in FIG. 11 to enhance Power Savings and allow for the Storage and Virtualization of both STARTs and STOPs.

FIG. 14: Further Enhancement of the Architecture in FIG. 13 to allow that only the analog circuits in the START signal path to be enabled during the detection of START event, providing additional power savings.

FIG. 15: Redrawing of prior art architecture from FIG. 4 for the purposes of clarity. Prior art implements the trigonometric identity of EQ2B: (cos α*cos ft)−(sin α*sin ft)=cos(α+ft).

FIG. 16: Waveform timing diagram of the Architecture presented in FIG. 15.

FIG. 17: Block diagram re-architecting of FIG. 15 with the differencing amp (205) removed and embedded or replaced by a comparator (206) for improved performance with reduced area and power consumption. Additionally, the START and STOP connections are reversed to result in an extracted angle of a rather than the angle of (360−α) extracted in FIG. 15. Additional blocks of a Digital Signal Generator or DSG (401) and a Digital I/O Processor or DIP (501) are added to complete the system architecture. The amplifiers, DACs, filters, and comparators comprise the Analog Front End (AFE). DSG has option to de-skew the digital generator to allow for phase corrections. This details the magnetic bridge (201, 211)) biases, details of Diff-SE Amplifiers (202, 212) reference levels, and DSG Digital Signal Generator (404) has optional phase correction added to the reference cosine signal which enables correction of AE Angular Error. The amplifiers, DACs, filters, and comparators comprise the Analog Front End (AFE). The Digital Signal Generator has a phase adjustment trim on the refence output of the DSG, the bridge biases are represented as are the single-ended references for the Diff-SE Amplifiers. The phase adjustment trim to the reference output cos(ft+f) of the DSG is an optional system enhancement for all configurations but not always shown for simplicity. Likewise, the Bridge and Diff-SE biases are not shown in all other figures for simplicity. Counter is an up-counter to extract angle α.

FIG. 18: Single Data Rate Complement Method: Similar to FIG. 17, but the START and STOP have been swapped such that the zero crossing of the reference cos ft is triggering the START at the beginning of the cycle. Instead of producing the angle α, the output is (360−α) degrees which is represented by the digital output MaxCount=StopCount. Also, the PWM gets inverted to become notPWM. The counter is an up-counter.

FIG. 19: Single Data Rate Count Down Method: Similar to FIG. 18, but the counter is counting down from full-scale which produces the angle α, at the time of the STOP event. The output is angle α which is represented by the digital output aStopCount. Also, the PWM is not inverted.

FIG. 20: Single Data Rate Complementary Method: Similar to FIG. 18, the START and STOP have been swapped (compared to FIG. 17) such that the zero crossing of the reference cos(ft) is triggering the START at the beginning of the cycle. The counter is an up-counter producing the output angle output is (360−α) degrees represented as the digital value aStopCount. The PWM is inverted.

FIG. 21: Single Data Rate Virtualized Count Down Method: Similar to FIG. 19, the START and STOP have been swapped (compared to FIG. 17) such that the zero crossing of the reference cos ft is triggering the START at the beginning of the cycle. The counter is a down-counter producing the output angle α represented as the digital value StartStopCount. The STARTs and STOPs are virtualized, but the DSG block is running in continuous mode with complete cycles. Thus, the START value is not at 360 degrees=0 degrees, but at a count slightly below 360 degrees. The comparators and the complete analog signal chain only need to be enabled around expected transitions, and the START comparator is only enabled occasionally to update for temperature changes.

FIG. 22: Double Data Rate Count-Down Method: Similar to FIG. 19, the START and STOP have been swapped (compared to FIG. 17) such that the zero crossing of the reference cos ft is triggering the START at the beginning of the cycle. But, here both the rising and the falling edges of both comparator outputs are used to generate STARTs and STOPs, effectively doubling the data rate. There are dual counters, dual PWMs, and dual angle outputs to support both rising and falling edge-based measurements. The counters are down-counters producing the output angle outputs ar and af as represented by the counter value at the time of the two STOPs generated in each cycle.

FIG. 23: Double Data Rate Count-Down Virtualized Method: Similar to FIG. 22, but all the STARTs and STOPs have virtualized as in FIG. 21 such that the zero crossing of the reference cos ft is triggering the START at the beginning of the cycle. There are dual counters, PWMs, and angle outputs to support both rising and falling edge-based measurements. The counters are down-counters whose START and STOP values are internally stored and differenced, producing the output angle outputs ar and af. Internal registers in the counter block store the START and STOP values for both rising and falling edge transitions. Power control and enabling of comparators and analog path is similar to FIG. 21.

FIG. 24: Double Data Rate Count-Up Method: Similar to FIG. 22, but the START and STOP have been swapped such that the zero crossing of the signal cos(α+ft) is triggering the START at the beginning of the cycle. There are dual counters, dual PWMs, and dual angle outputs to support both rising and falling edge-based measurements. The counters are up-counters producing the output angle outputs ar and af as represented by the counter value at the time of the STOPs.

FIG. 25: Multiple Sensor Incremental Update Mode with Count-Down Method is similar to Single Data Rate Virtualized Countdown Method with Multiple Sensor Pairs: Similar to FIG. 21 with an added multiplicity of sensor pairs. For simplicity, the bridge biases, and the option of generating the phase adjustable reference as cos(ft+f), are not shown. The DSG is able to jump between measurements of a multiplicity of sensors so that it can track between measurements thus tracking different angles of the different bridges without continuously sweeping from the START to the STOP values. Virtualization mode with Incremental update mode allows for the use of multiple pairs of off chip sensors connected by a MUX switch to be processed by a single angle extraction engine operating in virtualization plus incremental update modes. Operates in the incremental mode as described in FIG. 26.

FIG. 26: Incremental Mode Single Data Rate Virtualized Countdown Method: Similar to FIG. 21, but DSG is operating in non-continuous mode in which it is only active when zero crossings of the START and STOP comparators are expected. The Comparators, Analog Path, and the DSG are only intermittently activated to track thermal changes for some of the STOP events. The counter is a down-counter producing the output angle output is a represented as the digital value StartStopCount. Both the STARTs and STOPs are virtualized. The equation implemented is Equation 2B. Changing this architecture to be based on Equation 2A and using a count up counter is preferred and yields equivalent results.

FIG. 27: Direct Bridge Injection Mode. Functional equivalent to the system in FIG. 15, but the modulations and signal amplitude controls are incorporated into the DSG (406). DACs are removed from the signal path and instead incorporated into the bridge bias current sources. Likewise, the bridge bias current sources contain amplitude trimming and temperature compensation. This direct injection mode is applicable to all the architectural variations and all the signal processing methods that interpret the START and STOP edges to derive the value of the magnetic angle α.

FIG. 28: Block diagram of an example of a Digital Signal Generator that shows the structure of the Sine and Cosine wave generators and their relation to the DACs.

FIG. 29: Block diagram that shows of an example of a Digital Signal Generator with a simplified/reduced version of the Sine and Cosine wave generators in depicted in FIG. 28 that uses a common LUT for all functions, with each function having a dedicated Sequence-Counter to address the LUT.

FIG. 30: Similar to the Digital Signal Generator with Sine and Cosine Generators in FIG. 29, but the Cosine generator that produces an extra cos ft labeled CosData2 that is independent from the Cosine generator CosData1 which generates the digital cosine function used to produce cos α*cos ft.

FIG. 31: Digital Signal Generator Architecture that allows for three independently phase adjustable signals which may be connected to the three multipliers in all implemented AXEs which are labeled cos(ft+f1), sin(ft+f2), and cos(ft+f3). These allow for fine phase trimming.

FIG. 32: The Digital Signal Generator with Sine and Cosine Generators in FIG. 29, but the Cosine generator that produces cos(ft+f), which is independent from the Cosine generator that generates the digital cosine function used to produce cos α*cos ft.

FIG. 33: Block diagram that adds details and functions to the PWM/Counter that support power reduction modes and detail the operational properties of the PWM/Counter block.

FIG. 34: Block diagram that adds and details an incremental mode which allows for substantially reduced latency. Ref→STOP. Incremental mode only enables the Analog Extraction Engine and the DSG on demand when an angle determination is required. At all other times, most of the electronics are disabled, saving power.

FIG. 35: Block diagram that adds details and functions to the PWM/Counter that support the double data mode for a 2× reduction of latency.

FIG. 36: Waveform timing diagram that shows the relationship between the comparator rising edges and the angle α when operating in standard Single Data Rate Mode in FIG. 17. Ref→STOP.

FIG. 37: Waveform diagram of a double-data mode that shows the relationships between the rising edges of the two comparators which determines the angle αᵣ, but adds the relationships between the falling edges of the comparators which determines the angle α_{f}. STARTr and STARTf originate from the edges of cos(α+ft). Thus the STOPr and STOPf originate from the reference comparator as indicated by the notation: Ref→STOP

FIG. 38: Waveform diagram of a Double Data Rate Mode Count-Down Method that adds the relationships between the falling and rising edges of the comparators with respect to the angles aᵣ & a_{f}. START originates from the edges of cos(ft). START triggers a count down from ZERO to angles aᵣ & a_{f}. The Double Data Rate Mode Count-Down Method with Virtualized STARTs and STOPs is also represented by this waveform diagram. Compared to FIG. 37, the connections of the STOPs and STARTs have been swapped.

FIG. 39: Waveform diagram that shows the relationship between the standard operating mode and an example of incremental mode operation which retraces the temporal region of the last detected START.

FIG. 40: Waveform diagram showing the temporal regions in which the reference path and the signal paths need to be enabled to support detection of the zero crossings. These are indicated by the labels of “Enable Ref Path” and “Enable Measurement Path.”

FIG. 41: Countdown Method Architecture with START and STOP are swapped such that the rising edge of cos(ft) produces the START. The Counter counts down from 360 degrees and stops at a which is the value of the register Count. These changes to contents of FIG. 21 are not referred to in claims. Countdown Method Architecture with START and STOP are swapped such that the rising edge of cos(ft) produces the START. The Counter counts down from 360 degrees and stops at a which is the value of the register Count.

FIG. 42: Single Data Rate Countdown Method Waveform diagram for swapped START and STOP connections, as shown in FIG. 41 but implemented with a count-down counter, to the PWM/Counter with START sourcing from the cos(ft) comparator and STOP sourcing from the cos(ft+α) comparator. The PWM/Counter is operated in a count-down mode. The value of the angle counter is a at the time of the STOP signal. If the PWM/Counter is changed to count up, then the angle represented is a complementary angle of (360−α) degrees. (The complement of the angle α)

FIG. 43: Waveform diagram for an example of the both Incremental Update Method and the Single Data Rate Count Down Method using Virtualized STARTs and STOPs (with swapped START and STOP connections to the PWM/Counter such that START sources from the cos(ft) comparator and STOP sources from the cos(ft+α) comparator). The PWM/Counter is operated in a count-down mode. The Incremental Update Count-Down Method with Virtualized STARTs and STOPs is also represented by this waveform diagram. The bold overlays on the sinusoidal waveforms indicate temporal regions in the circuitry that are active. In the duration between these highlighted times, the only circuit that is required to be active is a master maintenance counter which coordinates and presets the counters in the DSG and the down-counter. In actual operation, the thick sections of the trace would terminate immediately after the STARTs and STOPs are detected.

FIG. 44: Waveform diagram using forward timing of the waveform generators. This allows the falling zero crossing of the cos(ft) comparator to provide the START signal with the falling zero crossing edge of the cos(ft+α) comparator. To provide the STOP signal. The PWM/Counter is operated in a count-up mode. Reversing the timing of the generators (like going backwards in time) is equivalent to the change between counting up and counting down.

FIG. 45: Waveform diagram using forward timing of the waveform generators. Using START on cos(ft) and STOP on cos(ft+α) to control an up-counter in the PWM/Counter results in a detected angle of (360−α) degrees.

FIG. 46: Equivalent to FIG. 45 Waveform diagram using forward timing of the waveform generators. Using START on cos(ft) and STOP on cos(ft+α) to control an up-counter in the PWM/Counter results in a detected angle of (360−α) degrees.

FIG. 47: A modification of FIG. 2 in which the reference signal to the START comparator is replaced with a signal originating from an inverted sine wave (−sin(ft)).

### DETAILED DESCRIPTION

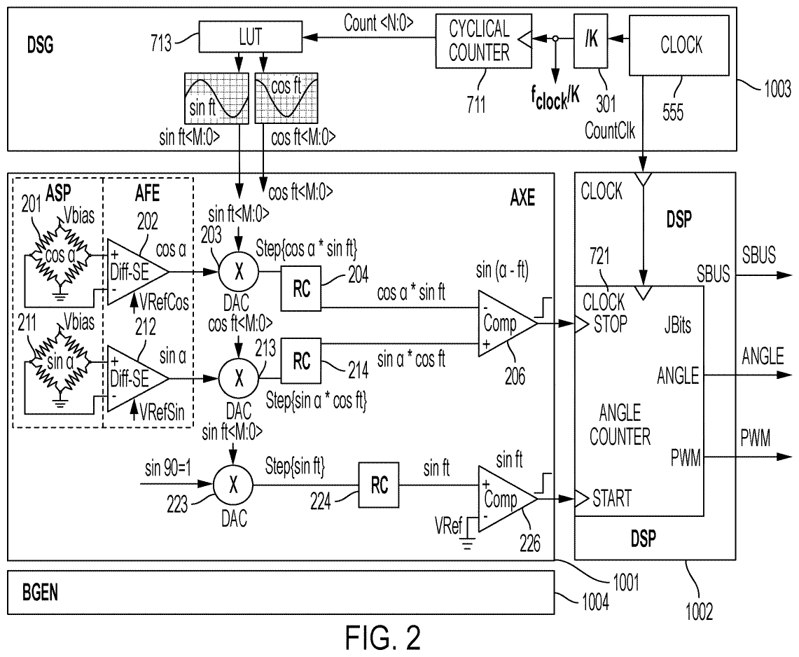

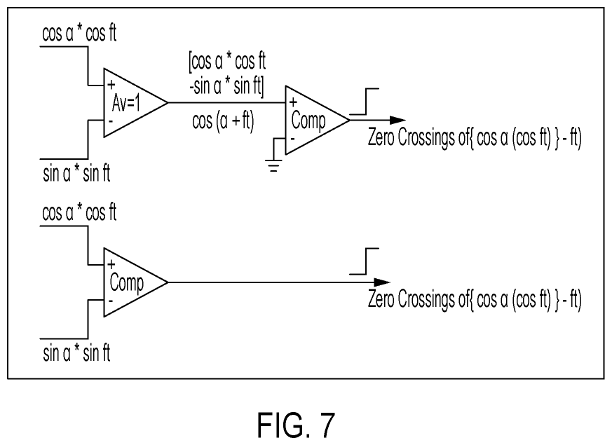

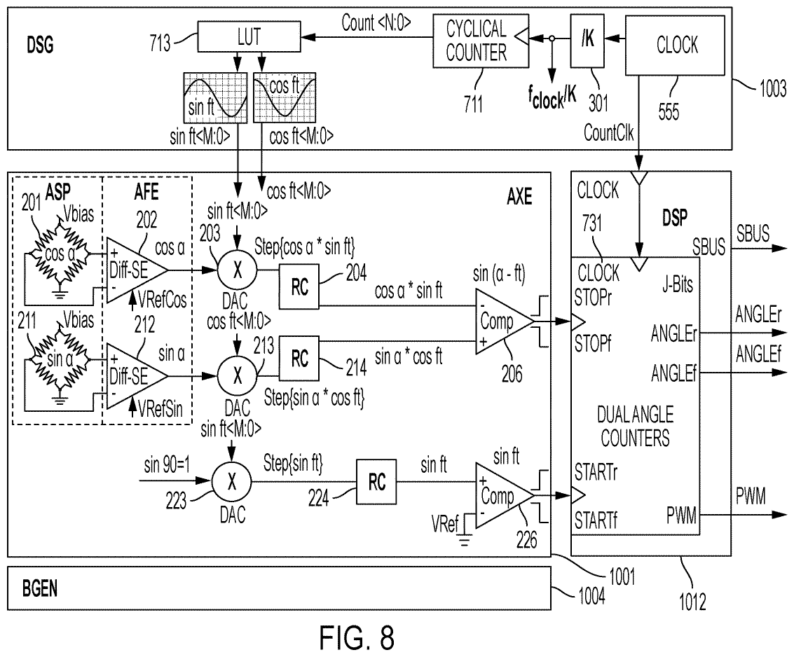

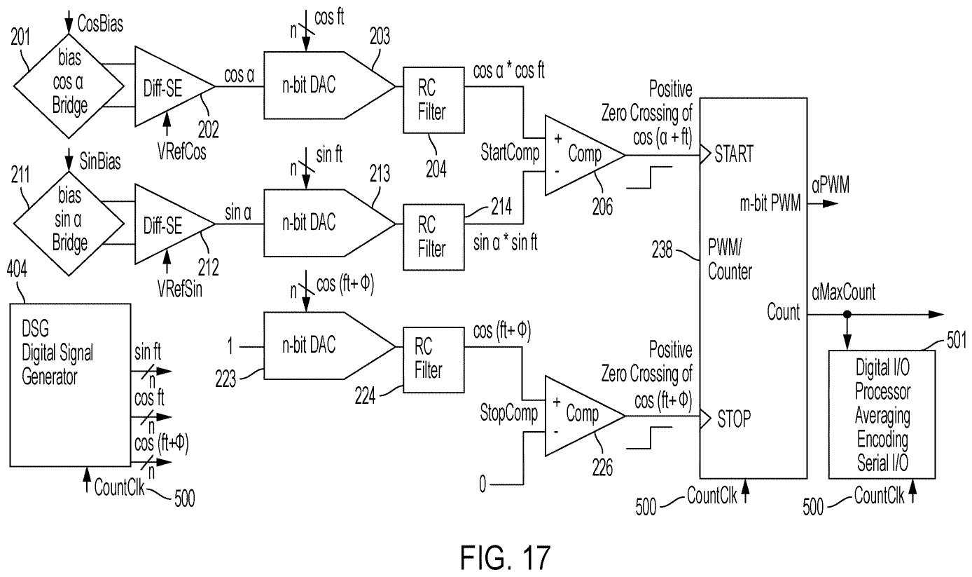

Only the zero crossing events of the sinusoidal waveforms need to be accurately preserved to extract the magnetic angle from the generated signals. Based on this observation a differencing amplifier used in other sensors like the '728 architecture can be replaced by the STOP comparator, as illustrated in FIG. 2, which is processing a difference between two signals rather than simply comparing a single signal to the ground reference. This allows the START and STOP paths to have equalized delays. FIG. 7 illustrates this virtualization of the differential amplifier. The upper circuit in FIG. 7 can be removed and replaced by the lower circuit. This fundamental change to the '728 architecture, in which the two inputs of the differential amplifier (labeled as Av=1) are now directly connected to the output comparator (206) in FIG. 17 removes unwanted delays in the signal path and enables improved and higher speed operation. Similarly, the equivalent substitution is applied to the architecture of FIG. 8 where the main difference between FIG. 8 and FIG. 17, is that FIG. 17 is based on Equation 2B whereas FIG. 8 being based on Equation 2A. Again, in FIG. 7 the top comparator responds to the zero crossings of the waveform cos(α+ft). The lower circuit eliminates the differential amplifier, but it still equivalently responds to the zero crossings of the waveform cos(α+ft). There is a significant difference between the two circuits in performance and delay time, but both circuits respond similarly to the Zero crossings. The upper circuit has added delays, distortions, and offsets due to the non-ideal aspects of a differential amplifier and adds significant power consumption. The lower circuit responds as though the virtualized differential amplifier has infinite speed, no distortions, and no offsets. This equivalency is utilized in the architecture illustrated in FIG. 2, saving power, cost, and improving accuracy.

The architecture illustrated in FIG. 2 is described in detail as follows. The magnetic bridges (201, 211) are biased with either a reference voltage or a reference current such that they each produce a differential output voltage in response to a magnetic field. They are substantially coincident but rotated 90 degrees apart such that one bridge (201) produces a varying signal that responds to the cosine of the angle α of the rotating magnetic field, and the other bridge (211) produces a varying signal that responds to the sine of the angle α of the rotating magnetic field. The differential to single-ended amplifiers (202, 212) convert each of the differential signals into single-ended signals.

The internal sine and cosine modulators (multipliers) are each based on a multiplying DAC (203, 213) that likewise respectively perform a multiplication of each of the analog sine or the analog cosine signals originating from the magnetic bridges (201,211) multiplied by each of the respectively internally generated digital sine and digital cosine modulating signals originating from the digital LookUpTable, or LUT, (713) as noted in Equation 2A, based on a digital look-up table herein known as a LUT (713). Thus, the analog cosine signal, cos α, originating from the magnetic bridge (201) is multiplied (via the DAC 203) by the M+1 bit digital sine signal, sin(ft) <M:0> (originating from LUT 713) to produce the analog staircase-like signal Step{cos α*sin ft}. Likewise, the analog sine signal, sin α, originating from the magnetic bridge (211), is multiplied (via the DAC 213) by the M+1 bit digital cosine signal cos(ft) <M:0> (originating from LUT 713) to produce the analog staircase-like signal Step{sin α*cos ft}.

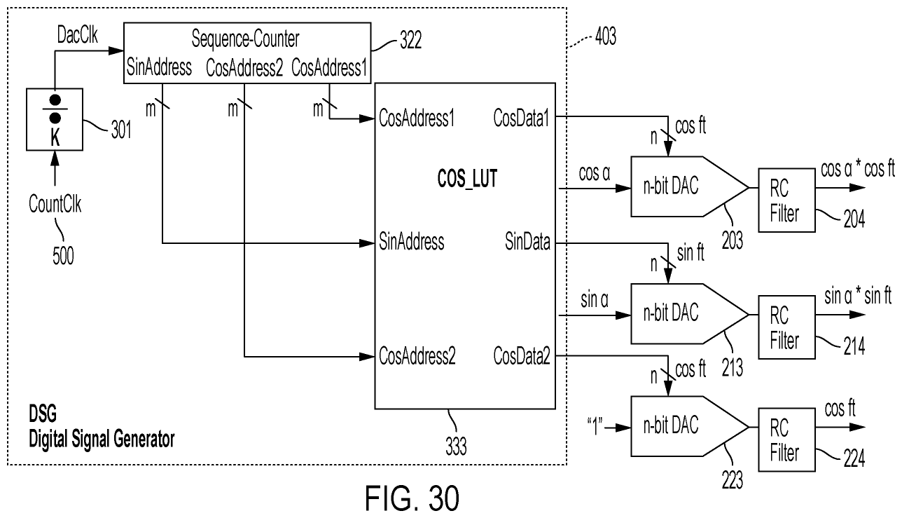

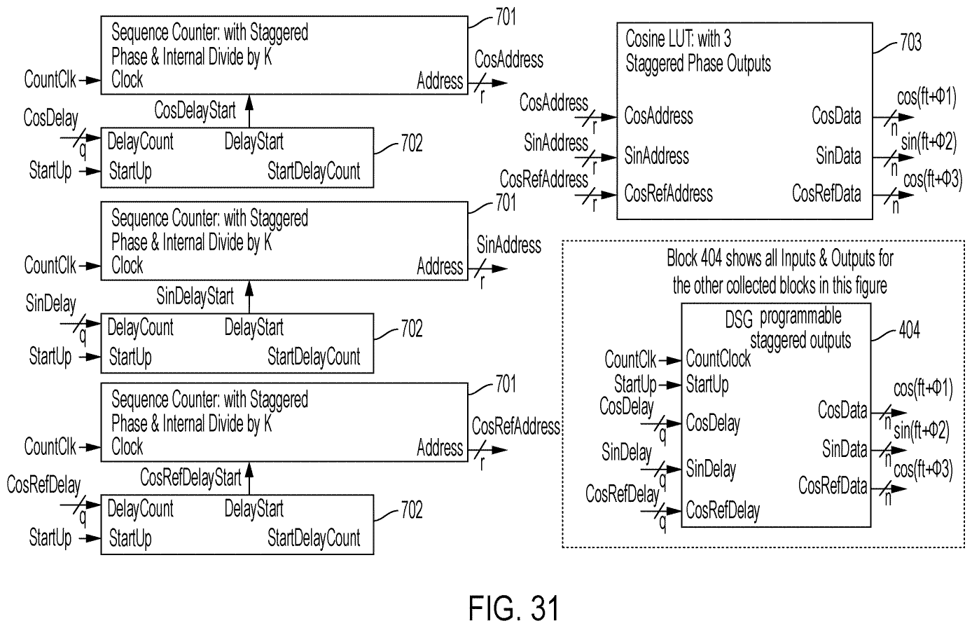

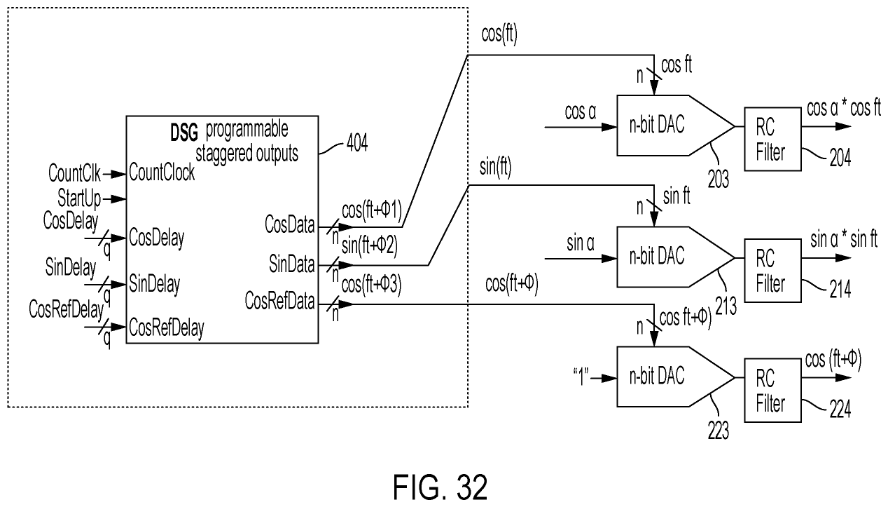

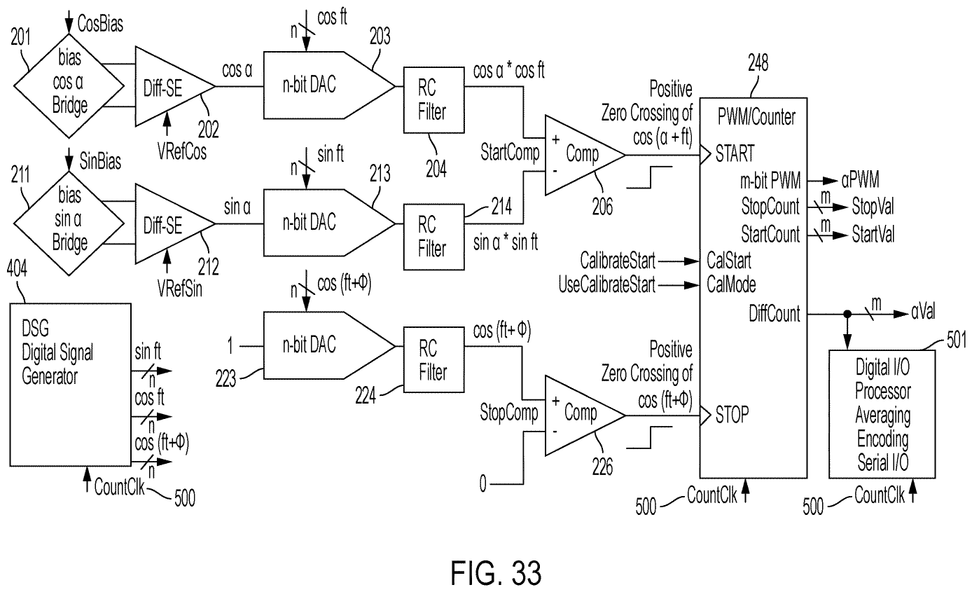

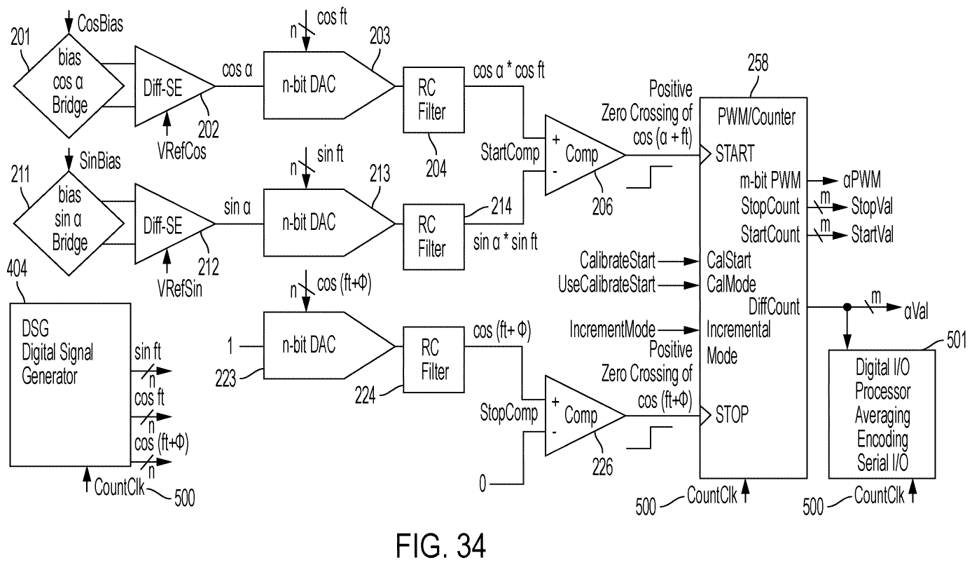

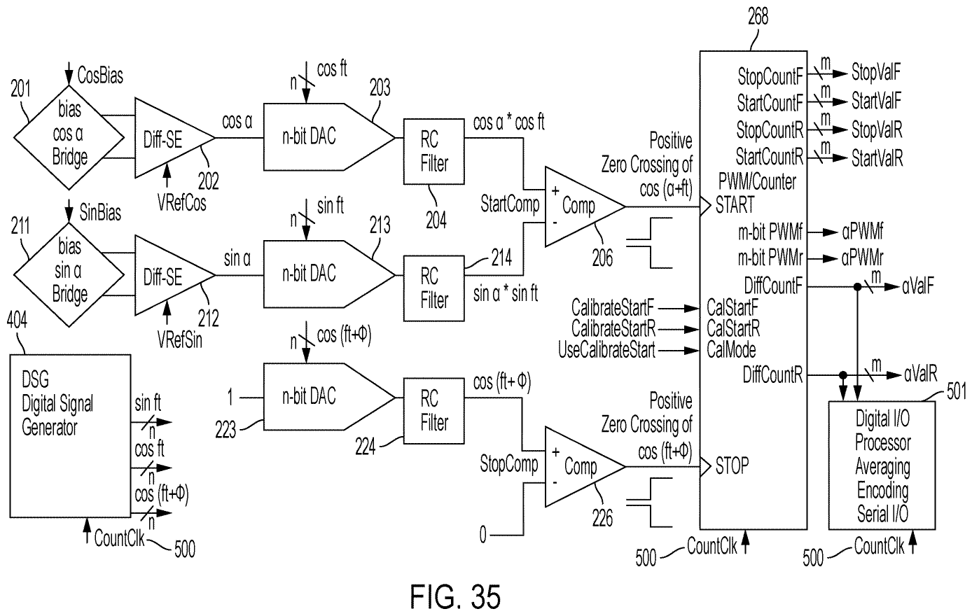

Enhancements to the cosine and sine signal generators inside the DSG shown in FIG. 2 are possible. These would allow for small independent phase variations to be applied to each of the digitally generated waveforms that connect to each of the 3 multipliers. These variations are diagrammed in FIG. 30, FIG. 31 and FIG. 32, FIG. 33, FIG. 34, and FIG. 35. In these diagrams a phase tweek is added to each of the signal generators which in noted as a symbol φ, for example wherein cos(ft) becomes cos(ft+φ). These variations are used to align the timing of the START vs STOP signal paths.

Unlike some other magnetic angle sensors, the digitally generated sinusoidal signals modulate the analog magnetic bridge signals, each resulting in an analog staircase waveform which are each smoothed out by a simple RC filter (204, 214). This method provides a more rapid calculation of angle α than previous implementations which require precision high order analog filters which have a longer settling time than a simple higher frequency first order RC filter (204, 214).

Some magnetic angle sensors use complex high order filters to convert a pair of 90 degrees out-of-phase square waves into a pair sine and cosine signals, which leads to a larger convergence time, which increases the latency from startup. In contrast, in implementations described herein, the outputs of the two RC filters are tuned produce the substantially smooth analog signal (cos α*sin ft) which connects to the negative terminal of STOP comparator (206) and the substantially smooth signal sin α*cos ft which connects to the positive terminal of START comparator (206).

Thus, the output of the STOP comparator behaves as though it is responding to the virtual signal sin(α−ft) which is equal to sin α*cos ft−cos α*sin ft, as given by Equation 2B. The reference signal's (sin ft) path is derived from the two inputs to the multiplying DAC (223): sin 90 degrees=“1” on the analog terminal and sin ft <M:0> on the digital input terminal, producing the analog staircase-like signal Step{sin ft} which is filtered by the RC filter (224) producing the substantially smooth analog signal sin ft. It is critical that all three RC filters are tightly matched (or trimmed to match), such that they contribute a substantially similar delay to all three signal paths which are connected to the two comparators. Both comparators are tuned to have tightly matched response times such that they have tightly matched delays.

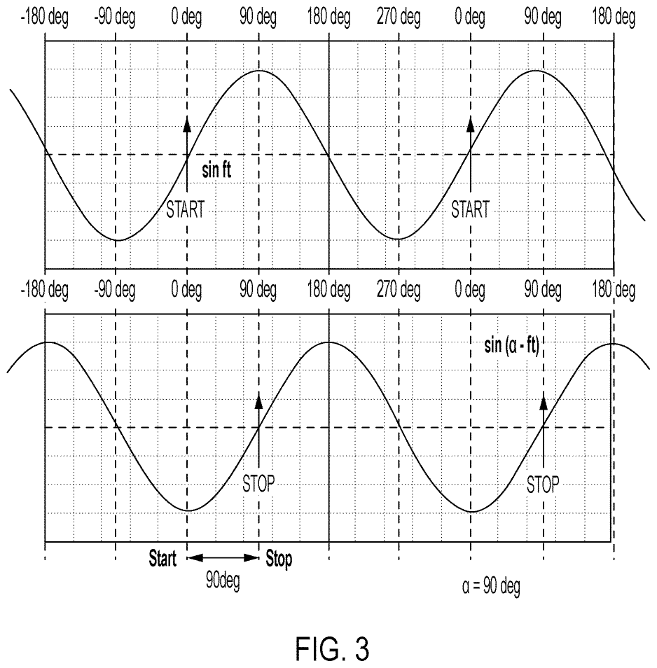

Thus, in reiterating equation 2A (Equation 2A: sin α*cos ft−cos α*sin ft=sin(a−ft)), the output of the STOP comparator produces a rising edge that is triggered whenever sin α*cos ft=cos α*sin ft and the difference between its two inputs transitions between a negative value to a positive value (positive slope). The comparator is only responding to the zero crossings and thus distortions in the signal only effect the results of the angle detection (if they are present) in the vicinity of the zero crossings. Likewise, the START comparator (226) produces a rising edge that is triggered whenever sin(ft) is crosses zero with a positive slope (only when it is transitioning from a negative value to a positive value. The START and STOP comparators (206,216) control the ANGLE COUNTER (721). The ANGLE COUNTER is cleared to a ZERO by each START signal and proceeds to count UP with each CountClk pulse from the system clock labeled CLOCK (555). The STOP signal stops and holds the count value as COUNT_HOLD. The counter continues counting until it overflows back to ZERO, at which time the held/stored count value COUNT_HOLD is presented as the ANGLE output of the ANGLE COUNTER (721) until the next cycle has been completed and the ANGLE output is again updated. The value of the ANGLE COUNTER represents as follows: A value of ZERO represents both 0 degrees and 360 degrees. If there are J bits in the counter, each incremental count will represent an angle change of 360/2^{J} degrees, which is the resolution of the Angle Sensor System. A full count of the ANGLE COUNTER represents a value of (360−360/2^{J}) degrees or (360*(1−1/2^{J})) degrees. The ANGLE COUNTER (721) is a J-bit counter. For any counter value COUNTX, the represented angle is given as ANGLEX=COUNTX*(360/2^{J}) in which COUNTX ranges from the decimal values of 0d to (2^{J}−1)d. Essentially, the numerical value of the counter is scaled and proportional to 360 degrees. It is noteworthy that due to the “/K” block (301) inside the DSG Digital Signal Generator (1003), that the sin ft and cos ft functions are updated by a factor of K less frequently than the ANGLE COUNTER, with the CYCLICAL COUNTER having a factor of K less count values as compared to the number of counts in the ANGLE COUNTER. This reduction factor of K is crucial to keeping the size of the LUT Look-Up-Table (713) compact enough to be cost effective and the allows the DACs (203,213,223) to operate at lower, more practical update frequencies. This slower operation of the DACs is possible due to two factors. Firstly, that the rate of change of the angle α is much slower than the rate of change of the angle ft. Secondly, that the RC filter smooths out the staircase like artifacts in the DACs'outputs, effectively interpolating the DAC outputs such that the DAC update rate does not impact the system behavior. The block BGEN, contains bandgap references, voltage references, and current references that are required to bias the magnetic bridges (201,211), the differential to single-ended amplifiers (202,212), the reference voltage labeled “sin 90=1”, and the ground reference voltage (VRef) of the START comparator which is at the same voltage as the zero crossing voltages of the sine and cosine waves which are the outputs of the DACs (203,213,223). The highest spin rate of the magnetic field that can be accurately measured by the system in FIG. 2 is determined by the constraint that the change in the angle α during a complete cycle of the cos ft or sin ft signal generator is at most 360*(1−1/2^{J}) degrees which is the minimum measurable increment of the angle α. FIG. 3 illustrates the relative timing between the waveforms that represent sin ft and sin(α−ft), indicating the locations of the START and STOP comparator rising edge signals when the angle α is at 90 degrees.

The DSP, Digital Signal Processor (1002) and the ANGLE COUNTER (721) have a PWM, Pulse Width Modulator output. This output is set to a logic HI at the event of the Start signal and is reset to a logic LO at the event of the STOP signal. Thus, the PWM has a duty cycle which is proportional to the angle α, with a 0% duty cycle at α=0 degrees, and a 100% duty cycle at α=(360−1*LSB) degrees. A 50% duty cycle represents approximately α=180 degrees. The angular velocity is inferred by calculating the change in the angle α from two adjacent measurements, divided by the change in time, the interval between measurements. Offsets in the comparators and in the input-amplifiers need to be addressed. Likewise, the gains of the two differential to single-ended amplifiers are trimmed to match closely such that a gain mismatch does not induce an error greater than the LSB of the ANGLE COUNTER. Additionally, the offsets of these two amplifiers either match or both are nulled such that they do not induce an error greater than the LSB of the ANGLE COUNTER.

### Description of General Operating Principles

### The Magnetic Angle Sensors

A numerical representation of a magnetic field's angle is extracted by processing a pair of electrical output signals from a pair of co-located magnetic angle sensors positioned orthogonally to each other. The signal processing methods used to extract the magnetic field angle utilizes a mixture of analog and digital signal processing.

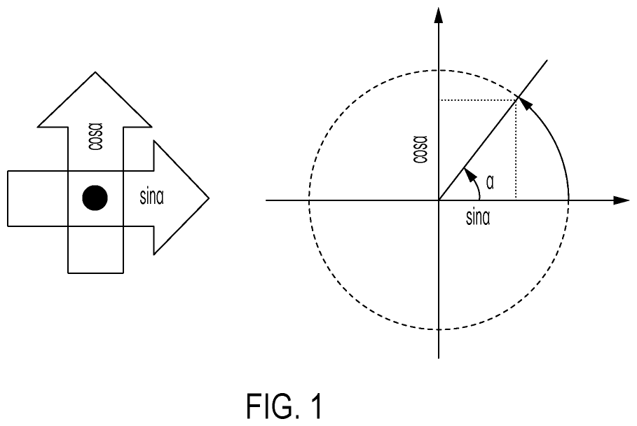

FIG. 1 illustrates an idealized pair of co-located angle sensors are positioned on a plane such that they are oriented orthogonally (90 degrees apart). A rotating magnet with its axis substantially perpendicular to the plane of the sensors generates a rotating magnetic field whose momentary angle of rotation is denoted as the angle α. The output of the vertically (y-axis) oriented sensor is proportional to the cosine of the magnetic field angle, and the output of the laterally (x-axis) oriented sensor is proportional to the sine of the magnetic field angle as Shown in FIG. 1. The z-axis of rotation is marked by a solid block dot at the physical center of both sensors. It the axis of rotation is displaced from the coincident center point, all content described herein is still applicable, but the amplitude and shape of the sine and cosine waveforms are modified due to this displacement. Calibration of the system outputs is then required to compensate for changes in output waveforms due to a given displacement.

### The Processing Signals From the Magnetic Angle Sensor Pair

One brute-force method of extracting the magnetic angle from a pair of magnetic angle sensors, is to digitize the pair of analog sensor outputs which are proportional to the sine and cosine of the magnetic angle. Subsequently, the digital values of the pair of signals are processed using a Digital Signal Processor (DSP). This process is succinct, since the DSP merely needs to implement a tangent function:

α=tan(cos α/sin α) Equation 1

However, this approach fails to be practical for at least three reasons: 1. The power consumption required for the DSP is much higher than the power consumption of any reasonable analog/digital hybrid approach; 2. The size of the DSP is much larger than the chip size of any reasonable analog/digital hybrid approach; and 3. The time to render an angle solution (latency) is much longer than any reasonable analog/digital hybrid approach. To avoid these problems the methodology described herein is an analog/digital hybrid approach.

### Improvements and Variations on the Basic Proposed Form Leads to a Decreased Latency and an Increased Rate of Angle Rendering

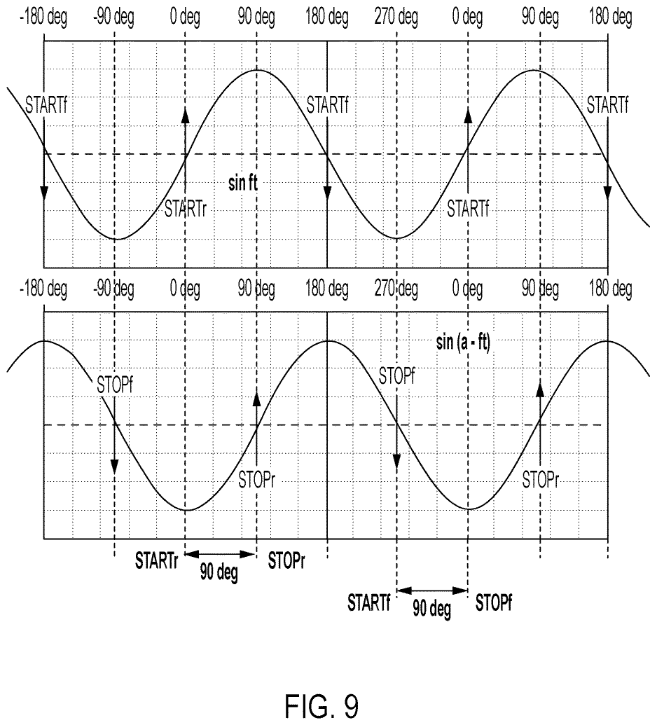

The above-described architecture as illustrated in FIG. 2 may be considered as a basic form which may be modified to result in various improvements to performance as are developed herein. The circuit in FIG. 2 extracts the START and STOP signals to the Angle Counter base on rising-edge/positive-slope zero crossings of the comparators' differential inputs which result in a rising edge of the comparator outputs as illustrated in the waveform plot in FIG. 3. Alternatively, the rate of extraction may be doubled by also processing the falling edges of the comparators to produce an additional pair of STOPs and STARTs (in each cycle) which will be 180 degrees delayed from the pair of STOPs and STARTs originating from the rising edges of the comparator outputs. This architecture is illustrated in FIG. 8 while the timing waveforms are illustrated in FIG. 9. The ANGLE COUNTER from FIG. 2 (721) is replaced by a DUAL ANGLE COUNTER (731) which has as its inputs a pair of START signals, STARTr and STARTf, and a pair of STOP signals, STOPr and STOPf, which are now sourced from both the rising and the falling edges of the STOP and START comparators. The DUAL ANGLE COUNTERS have dual angle output registers, ANGLEr and ANGLEf, which are alternately updated at a 180-degree stagger. The PWM may be sourced from either the rising or falling counters.

### Offset Reduction Methods Improve Accuracy

### Chopper Stabilized Amplifiers and Precision References

The architecture in FIG. 2 is vulnerable to several offset mechanisms which will induce angle measurement errors. The differential to single-ended amplifiers (202, 212) are required to be low input offset current and zero input bias current. Chopper stabilized operational amplifiers may be utilized to construct these amplifiers because the input signal frequency range due to changes in the angle α are relatively low when compared to the inputs to the comparators. Additionally, VRefCos, VRefSin, and VRef must be precisely matched.

### Chopper Stabilized Comparators

The comparators (206, 226) are low offset to avoid inducing angle errors. Common precision design methodologies will reduce the offsets, but greater precision and thus greater accuracy is possible. Normally, it is not practical to chopper stabilize a comparator. Amplifiers are chopper stabilized by swapping devices in their input stages at frequencies substantially higher than their signal range of operation and then the outputs are filtered to remove the chopping glitches and artifacts. This is not usually possible in a comparator. However, in the architecture of FIG. 2, it is possible to chop/flip the input stages of each comparator (206, 226) immediately after each comparator has detected an edge transition. This is possible since there will be nearly an entire operating cycle before another transition is detected since the rate of change and thus any change of α is small comparted to the duration of an operating cycle. Thus, any pair of operating cycles will have the comparators producing complimentary offsets which may be effectively averaged to nearly zero offset. This requires that each pair of cycles is averaged since there will be an alternation between a small phase lead and a small phase lag between any pair of cycles which is induced by flipping the input stage (and thus flipping the input stage offset. Although the precision may be dramatically increased using this method the angle rendering rate is halved in this mode because two samples are used which are averaged to produce one sample of higher resolution. Using chopper stabilized comparator which toggle polarity with each alternating cycle of operation allows the results of 2 adjacent cycles to be averaged with perfect offset cancellation. The cost is a 2× reduction in the angle rendering rate. Using the Double Data method architecture mode would compensate for this loss.

### Virtualized Start and Stop Counts Improve Accuracy

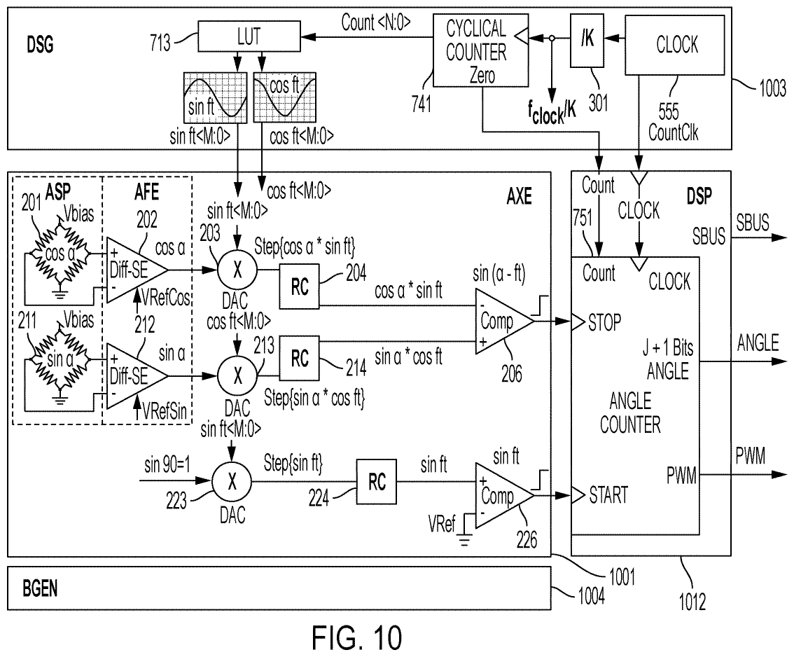

In all previously discussed architectures, the START signals trigger the start of an up-counter which counts up from Zero until the counter receives a STOP signal. The value of the counter at the time of the START signal is always Zero and the value of the counter at the time of the STOP signal represents the angle. The maximum possible count which represents both 0-degrees and 360-degrees is a full count of the J-bit counter in which it overflows back to the count of Zero. It is possible to improve the resolution of the system by effectively reducing noise in the START comparator by altering the ANGLE COUNTER. The architecture from FIG. 2 is enhanced to support a virtualized START as illustrated in FIG. 10. The ANGLE COUNTER (751) has an extra bit added (J+1) and no longer uses the START signal to begin counting. Instead, the CYCLICAL COUNTER (741), which controls the generation of the digital sine waves produced by the LUT (713), triggers the ANGLE COUNTER's (751) up-counting when it produces a “Zero” signal that coincides with the rising-edge zero-crossing of the reference sine wave. After some delay time inherent to the electronics, the Reference Comparator (226) produces a START signal. The DSP block (1002) saves the value of the ANGLE COUNTER (751) which continues to count up until it receives a STOP signal from the Signal Comparator (206). The STOP value of the ANGLE COUNTER (751) is stored by the DSP block (1002). The DSP differences the START to STOP counter values to calculate the current value of the magnetic angle α, but it also stores a copy of both the START and STOP counter values. The DSP is thus able to calculate and maintain a running average of the START values which may be used to improve the angle calculations by removing analog induced noise (especially comparator noise) from the START value. Additionally, under conditions in which the angle α is static, or changing very slowly, the averaging of the STOP values may be similarly used to improve accuracy. Thus, in summary, virtualization of the START and STOP values may be utilized to improve the accuracy of the extraction of the magnetic angle α.

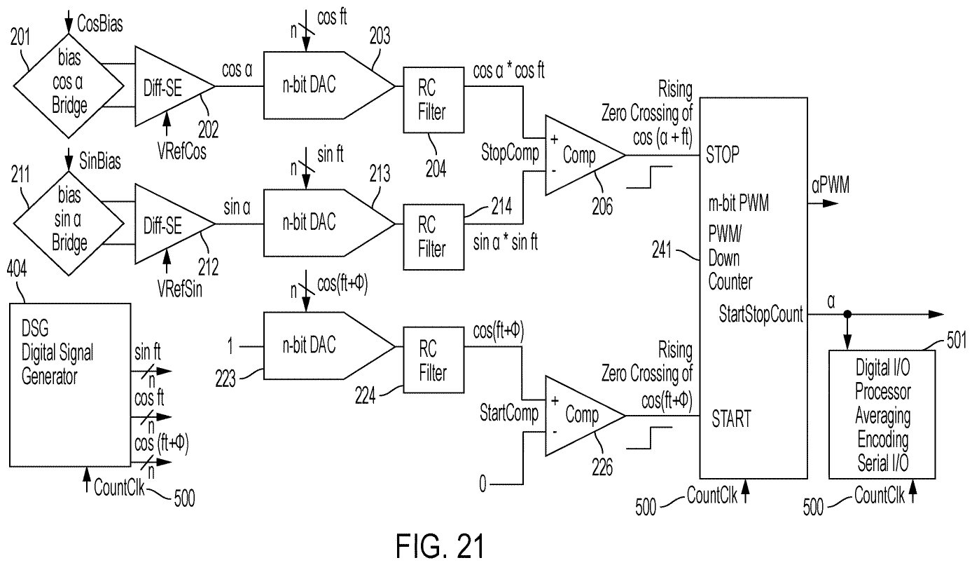

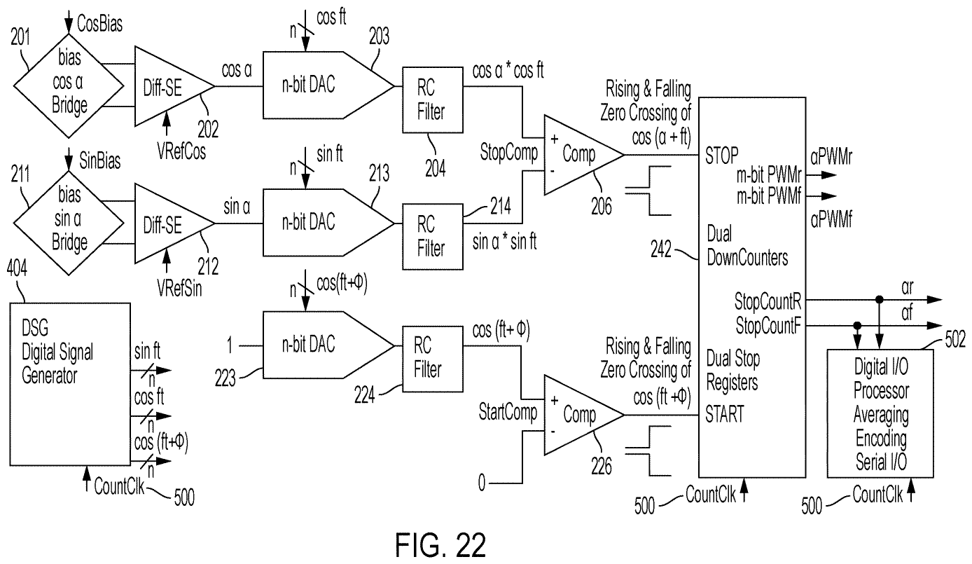

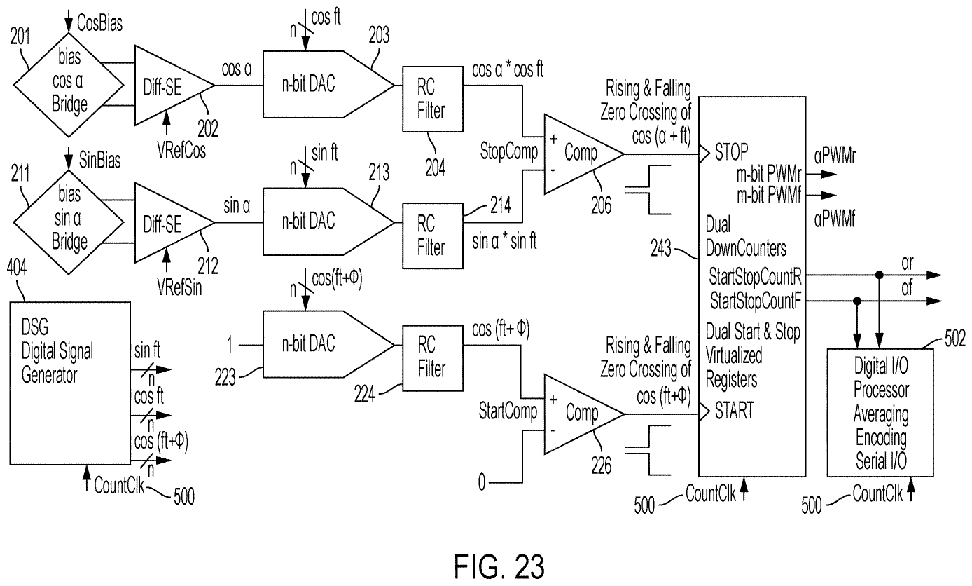

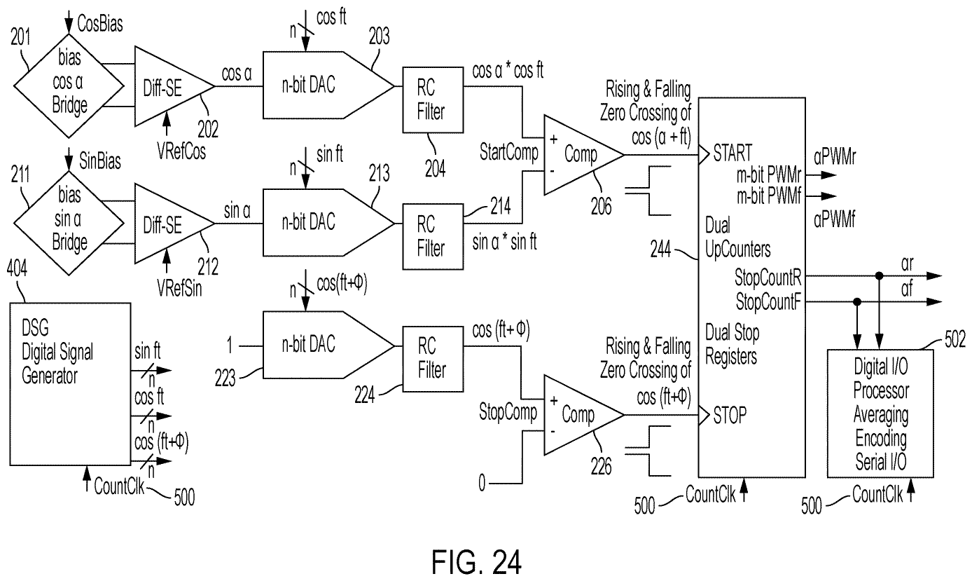

Double Data Rate Count-Down Virtualized Method: The architecture is illustrated in FIG. 23. It is similar to FIG. 22, but all the STARTs and STOPs have virtualized as in FIG. 21 such that the zero crossing of the reference cos ft is triggering the START at the beginning of the cycle. There are dual counters, PWMs, and angle outputs to support both rising and falling edge-based measurements. The counters are down-counters whose START and STOP values are internally stored and differenced, producing the output angle outputs ar and af. Internal registers in the counter block store the START and STOP values for both rising and falling edge transitions. Power control and enabling of comparators and analog path is similar to FIG. 21.

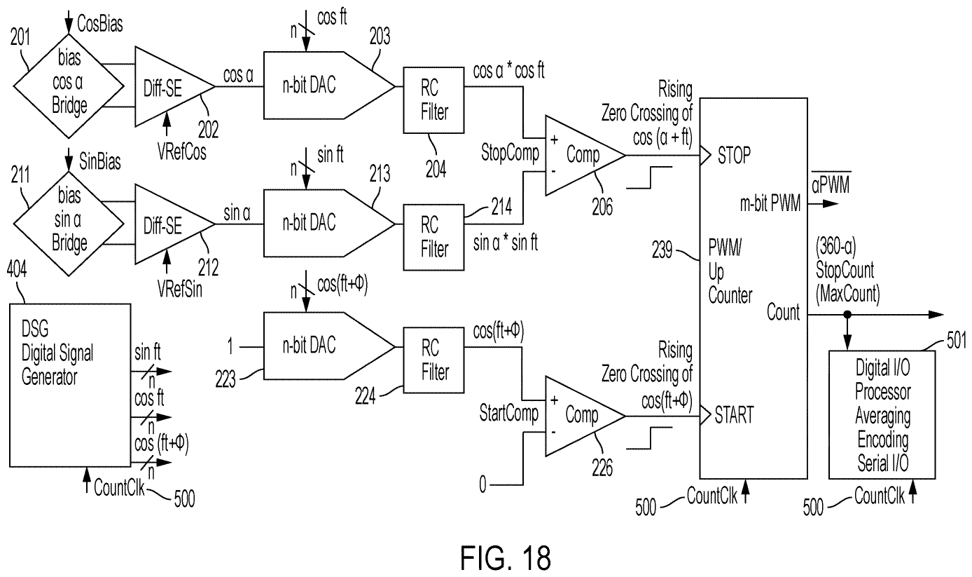

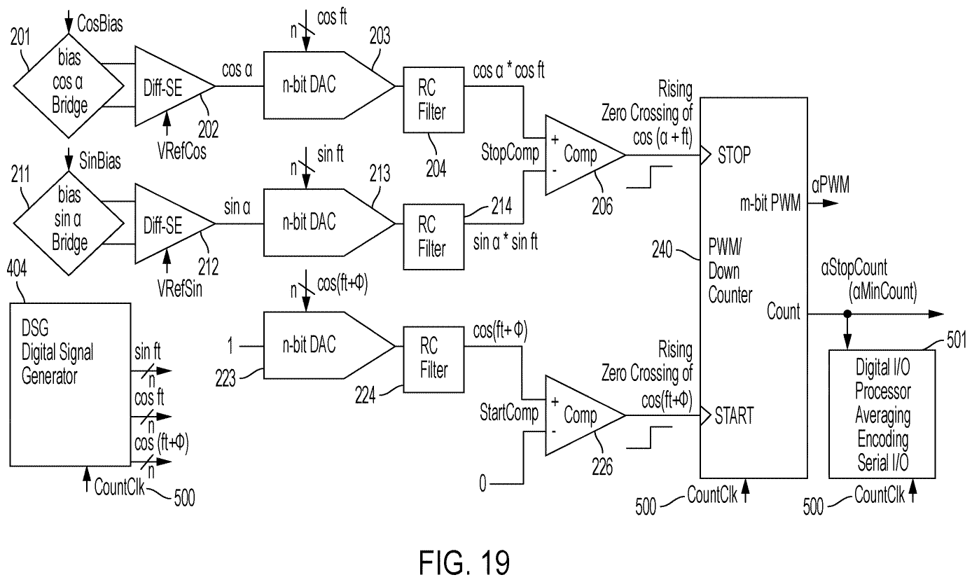

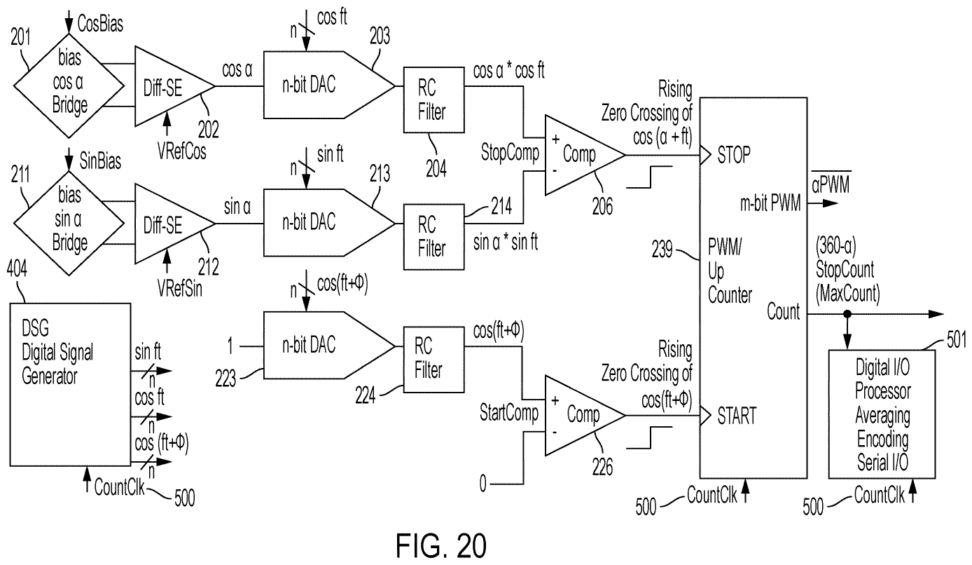

FIG. 20: Single Data Rate Complementary Method: FIG. 20 illustrates an implementation of a single data rate complementary method in which the rendered angle is not the angle α but the angle of (360−α) degrees. Similar to FIG. 18, the START and STOP have been swapped (compared to FIG. 17) such that the zero crossing of the reference cos(ft) is triggering the START at the beginning of the cycle. The counter is an up-counter producing the output angle. Generally, changing form a count-down to a count up, or the reverse change toggles the result from α to (360−α), or the reverse. Likewise, swapping the START and STOP signals in the architecture toggles the result from α to (360−α), or the reverse.

### Reduced Power is Accomplished by Disabling the AXE Using CYCLICAL COUNTER Data

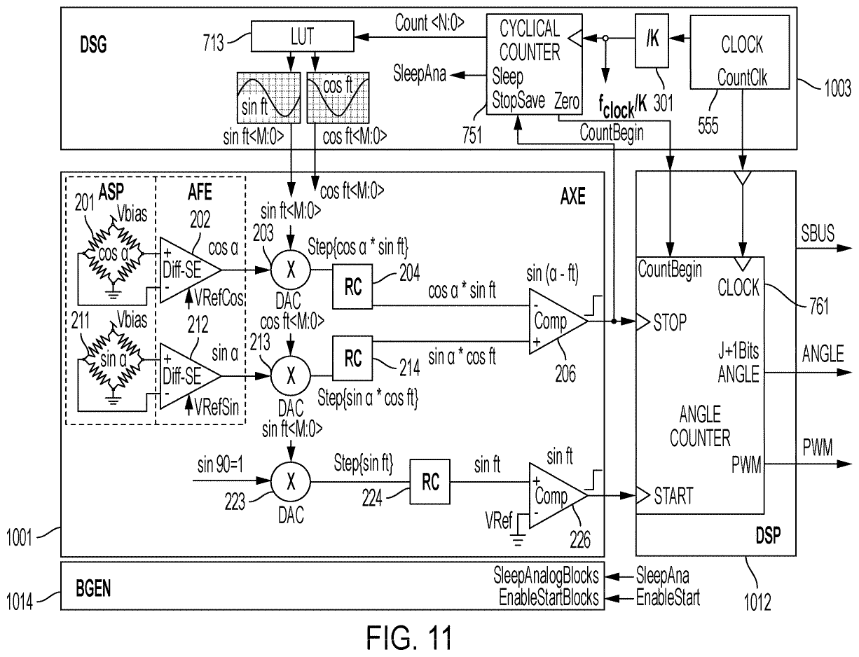

FIG. 11 is a modification of FIG. 10 in which a substantial power reduction is implemented by temporally disabling (or sleeping) the analog blocks in the AXE (1001) when they are not in the temporal vicinity of a zero cross event as registered by the comparators (206, 226). The temporal position of the START signal has little variation from one START to the next START. Thus, the AXE must always be enabled (at a time which is predictable) before the CYCLICAL COUNTER (751) reaches ZERO. The AXE is disabled immediately after the START signal occurs unless the previous STOP signal was in the temporal vicinity of the START signal. After the STOP signal occurs, the AXE is disabled unless the STOP occurs just prior to the next START signal. The CYCLICAL COUNTER (751) stores the value of the most recent STOP signal to allow for the above conditions to be calculated. Generally, the position of the STOP signal has only small variations from cycle to cycle due to the relatively low rate of change in the magnetic angle α. The net result is that the entire system is almost completely shut down for the majority of each cycle after an initial angle acquisition occurs. There is a required margin that is added to the re-enabling mechanism to account for the circuitry settling time of the entire AXE (1001) system. This is highly dependent on the specifics of the implementation of all the blocks in the AXE, but it is reasonable to expect that the net power savings are substantial. Since the value of the last STOP is stored and updated inside the CYCLICAL COUNTER after each cycle, adding timing margins is possible to ensure that the system does not miss the next STOP event. Note that the temporal location of the STOP event is stored as a function of the CYCLICAL COUNTER's values and not the exact count from the ANGLE COUNTER. The values of the CYCLICAL COUNTER are much coarser (by a factor of K) than those of the ANGLE COUNTER. This low power method may be used in all of the architectural and functional variations of the architectures described herein.

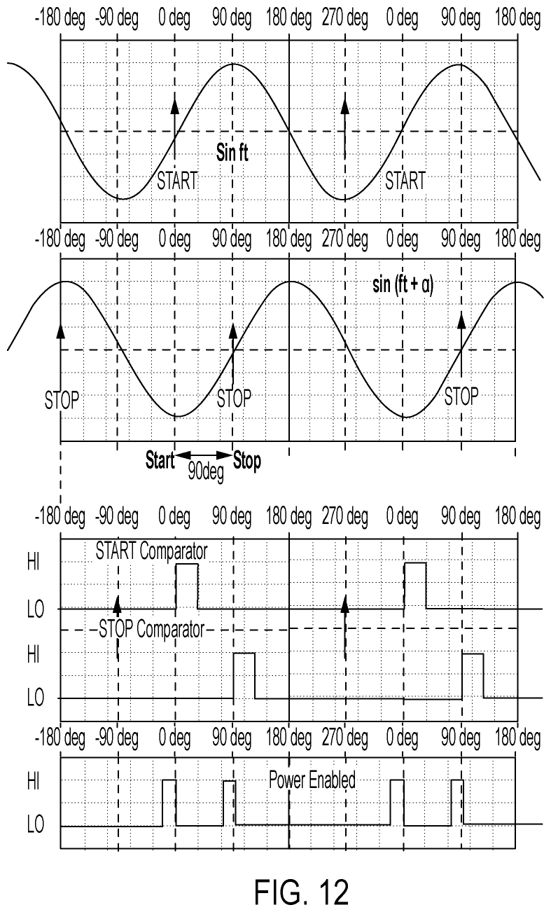

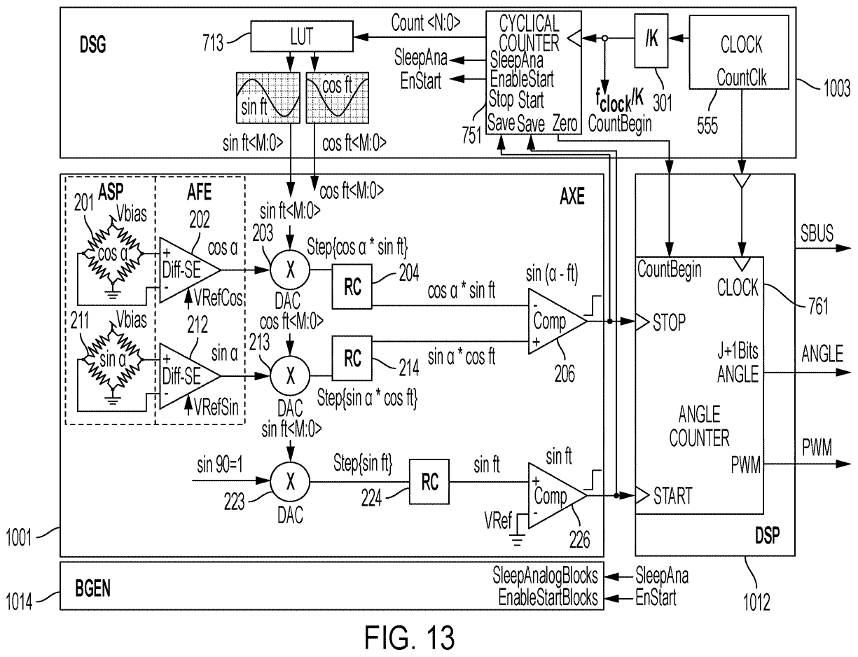

FIG. 12 and FIG. 13 illustrate the typical the timing of the STARTs and STOPs which are the outputs of the START and STOP comparators at a non-specific single angle α. There are many possible variations of the comparator behaviors which are dependent on the exact implementations and the required enable time margins. In the example provided, the comparators have a fixed persistence after they are triggered HI; after that persistence time, they return to the low state. The timing for the enabling of power, Power Enabled, incorporates a fixed pre-turn-on margin that turns on the power sufficiently in advance of the expected timing of the START and STOP events to allow all the analog circuitry to adequately settle such that accuracy is not affected by turn on transients. In addition to the analog circuitry being disabled, the LUT (713) may also be disabled to save power. The sin ft and sin(α−ft) plots are shown without considering that the analog circuitry has been disabled. The sinusoidal function will only be briefly present while the power is enabled. There will be an initial glitch after the power is enabled and a subsequent settling interval after which the wave forms will match the graph shown. After the power is disabled, and until the next enabling of the Power signal, the analog waveforms will not match the plotted waveforms. In an actual implementation, these sinusoidal analog waveforms will either be floating in a high impedance state at some arbitrary voltage, or they may be forced to a known and planned state. Their exact value is not critical to any implementation. In the case in which the STARTs and STOPs are sufficiently close, the pairs of Power Enable pulses may actually merge into a single pulse. In all of the possible cases, it is clear that power is substantially reduced by employing this architecture. Generally, Power Enable pulses are terminated by the detection of either a START or a STOP event. There is always a fixed Power Enable pulse (EnStart in FIG. 13 connected to BGEN (1014)) pulse which occurs before the Zero Count of the Cyclical Counter (751) to allow the registration of the START time in the Angle Counter (761). If an expected STOP event is expected to be in temporal proximity to the START event, then the detection of a START will not terminate the Power Enable pulse. Termination of the Power Enable Pulse, in this case can only occur after both a START and a STOP have been detected. Furthermore, when a START event is anticipated to occur, the AXE (1001) need only enable the circuits in the START path (223, 224, 226) since the rest of the circuits in the AXE are required only when a STOP is expected. In the case of an Expected STOP, the whole AXE (1001) must be enabled in advance of the expected STOP, based on the temporal location of the previous STOP.

### Partial Cycle Rendering (AKA Incremental Mode): Reduced Latency is Accomplished by Manipulating the CYCLICAL COUNTER to Only “Trace Over” Temporal Regions in Which Positive Zero Crossing Events Occur

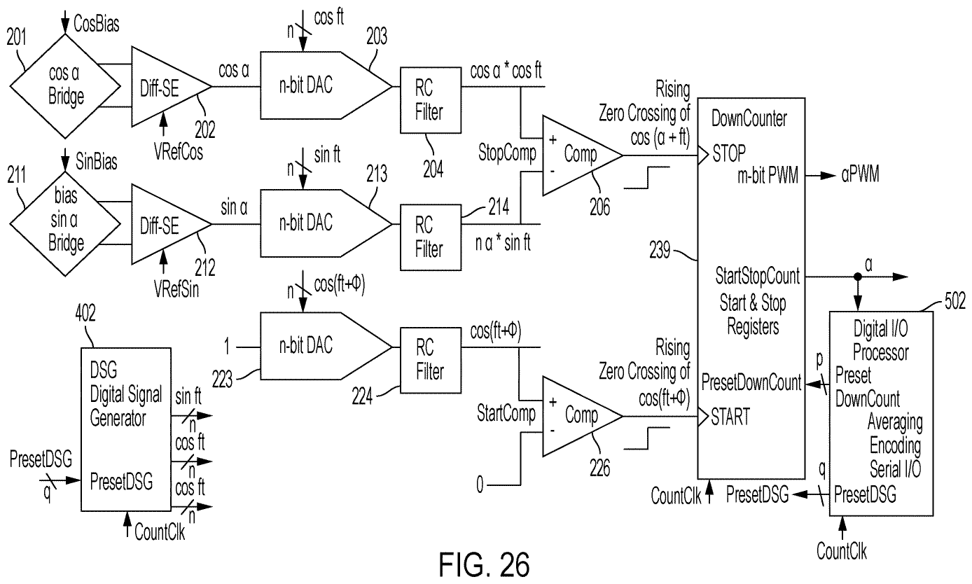

In the previous paragraphs, the Cyclical Counter (751) in FIG. 11 is continuously cycling from count 0 to the maximum count, and then overflowing back to count 0 such that the sin ft and cos ft digital generators in the DSG (1003) are continuously producing sine and cosine digital numerical streams comprising a sequence of digital words which are each M+1 bits. Since during a majority of each cycle the SleepAna signal emanating from the Cyclical Counter (751) is active and is thus powering down the AXE (1010) as shown in the Power Enabled graph in FIG. 12, it is obvious that there is a lot of deadtime in each cycle during which the entire circuit is not required to produce any results. Although the circuit is inactive for a majority of each cycle, a full operating cycle of the sine and cosine waves is required for each angle update result that is produced. Since this is true, it is evident that a new operating mode for the circuit may be defined in the sine and cosine generators and the AXE (1010) in which most of the circuits (except for the clocks and counters) are only active for the duration of the two PowerEnable pulses on the Power Enabled trace in FIG. 12, but additionally, the cyclical counter only produces the Count values that correspond to the two active sections of the Power Enabled pulses, and additionally these two active intervals may occur back-to-back. Thus, the START and STOP results are rendered in a small fraction of the entire sinusoidal cycle. Thus, an angle α is rendered in a small fraction of the previous rendering time which requires a full cycle. Furthermore, since the position and counter value corresponding to the START event is substantially similar from one cycle to the next, and only varies due to system noise, the temporal section of operation corresponding to the START event may be eliminated during most operating cycles. This further reduces the rendering time per angle α. For the purposes of tracking thermal and other temporal system variations, the START counter value needs only be updated for a small percentage of operating cycles. This above operating mode may be labeled “Partial Cycle Rendering” and enables the latency/rendering time to be faster than any completive method and implementation. To implement this a signal StartSave needs to be added to the CYCLICAL COUNTER (751) in FIG. 11 which taps into the START signal emanating from the AXE (1001) and connecting into the CYCLICAL COUNTER (751) similarly to how the StopSave signal is generated. This StartSave is shown in FIG. 13. Additionally, FIG. 13 adds a selective signal EnableStart, which only enables the circuits in the START signal path during START events. FIG. 13 is a modification of FIG. 10 and FIG. 11 in which the ability to selectively control the LUT (713) such that it only generates the portions of the sin ft and cost ft waveforms in proximity (before) the (sin ft) and sin(α−ft) waveforms are expected to contain rising edge zero crossings (STARTs and STOPs). FIG. 26 illustrates an architecture that supports the Incremental Mode (aka Partial Cycle Rendering Mode).

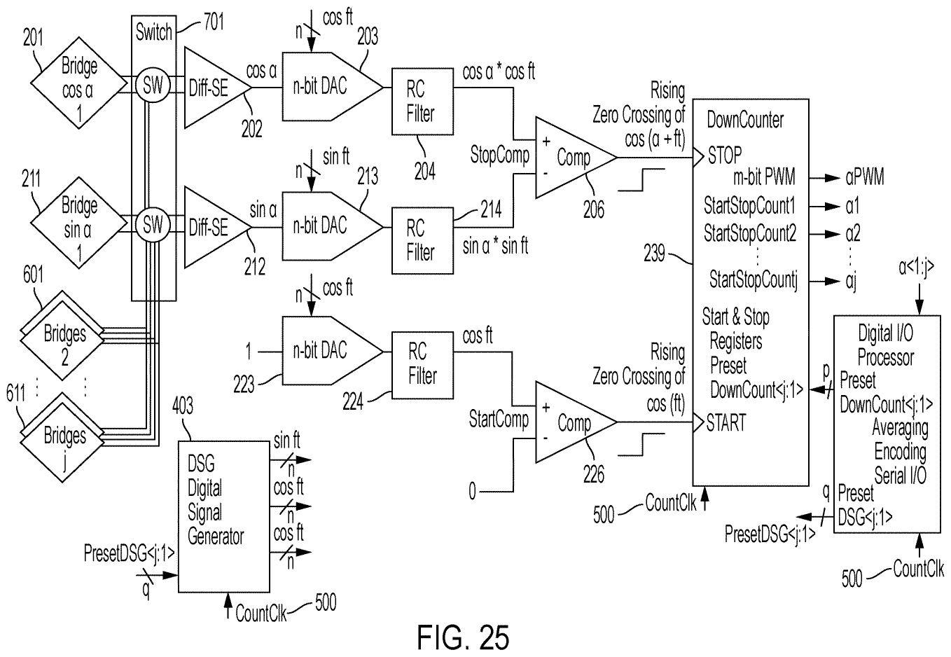

Multiple Sensor Implementation is Made Possible Using the above Partial Cycle Rendering Mode: FIG. 25 illustrates a Multiple Sensor Incremental Update Mode with Count-Down Method which is similar to Single Data Rate Virtualized Countdown Method with Multiple Sensor Pairs: Similar to FIG. 21 with an added multiplicity of sensor pairs. For simplicity, the bridge biases, and the option of generating the phase adjustable reference as cos(ft+φ), are not shown. The DSG is able to jump between measurements of a multiplicity of sensors so that it can track the different angles of the different bridges without continuously sweeping from the START to the STOP values. Virtualization mode with (AKA update mode allows for the use of multiple pairs of off chip sensors connected by a MUX switch to be processed by a single angle extraction engine operating in virtualization plus incremental update modes. Operates in the incremental mode as described in FIG. 26.

### Summary of Above Variations in Implementation

So far, there have been seven variations described:

There are several variations of such a circuit which can be implemented. For example, a single data rate count-up method uses up-counting angle extraction, which only utilizes the rising edges of START and STOP comparators. The extraction of angles is a continuous process in which an angle is periodically rendered.

As another example, a double data rate count-up method uses a modification to the circuit in which both the rising and falling edges of the START and STOP comparators are utilized to extract the angle. However, in this implementation, there are two extractions of the angle occurring in each operational cycle. These extractions occur 180 degrees apart from each other. The extraction of angle pairs can be a continuous process in which a pair of angles is periodically rendered.

As another example, virtualized rendering of the START event uses a circuit in which the START events are virtualized and averaged as a value of a cyclical counter and no longer are extracted in every operating cycle. A stored and averaged value is maintained and only gets refreshed frequently enough to account for thermal variations. In this mode, a single angle is extracted in each operational cycle.

As another example, double data rate with virtualized rendering of the START Events uses virtualizations of the START events, but by using both rising and falling edges two extractions of the angle may occur in each cycle.

As another example, pulsed power operation involves only enabling the AXE previous to expected START and STOP events to reduce power consumption.

As another example, partial cycle rendering reduced latency by manipulating a cyclical counter to only count out or “trace over” temporal regions in which positive zero crossing events occur. In this implementation a circuit is continuously operational, but the counter is initially stepping through the numbers that are prior to the START event and thus capture the START event. Subsequently, the counter jumps to a count that is prior to the count corresponding to the last STOP and thus captures a STOP event. This sequence can be repeated indefinitely. The numerical values of each START-STOP pair are differenced to render the angle. This sequence can repeat indefinitely producing an angle for each counter pair. A settling time margining can be added to each START and STOP acquisition to ensure that all analog circuits in the signal path have fully settled after being enabled. Optionally, the analog circuits can be all continuously enabled, in which case the counter jumps to a value that is prior to the last START and then the last STOP, with a timing margin allowing for the analog circuits to settle. The rate at which an angle is rendered may be one tenth of the rendering time of other implementations. To keep all rendering times uniform, a variable non-operational delay time may be added to each operational cycle. Thus, each cycle contains a START duration, a STOP duration, and a NOP (non-operational) duration.

As another example, partial cycle rendering with virtualized STARTs includes a circuit in which typical cycle, only a STOP is rendered. The START value is derived from an intermittent running average of START measurements are only updated enough to account for thermal drift. In this implementation, an additional cyclical counter, lookup table, and sin(ft) signal chain might optionally be added to extract START event measurements in parallel with STOP event measurements. These added components are much smaller than the components utilized to operate the STOP event measurements. This reduced size is due to the fact that while STOP events can occur at any arbitrary value of the cyclical counter, START events always occur near the beginning of each cycle and only a small range of counts is required to measure a START. To produce START events, only a small portion of a full cycle is required to be generated, and the value of this sub-count is always identical.

The system for extracting an angle from a magnetic field illustrated in FIG. 2 in which an Analog Sensor Pair (ASP) which is a pair of co-located orthogonally oriented angle sensors which are properly biased and respond to a magnetic field of orientation a, such that each sensor produces an analog voltage. Sensor cos a produces a differential analog signal proportional to cos α. Sensor sin α produces and differential analog signal proportional to sin α.

An Analog Front End (AFE) processes the pair of differential signals, which are outputs of the ASP block, converting them into a pair of single-ended analog voltages while correcting the signal gains, matching the signal amplitudes, and reducing the offsets. This pair of signals is labeled as sin α and cos α.

The sin α and cos α pair are each connected to the analog inputs of a multiplier marked as X, which is implemented using a multiplying DAC which multiplies an analog voltage by a digital number. The digital signals to these DACs are a pair of M+1 bit digital words which are updated at a clock rate of fc_{lock}/K which originate from the Digital Signal Generator block (DSG). Two digital signals sin ft<M:0> and cos ft<M:0> are sent to the digital inputs of the DACs such that they modulate or multiply the analog input signals by the digital input signals. DAC 203 receives the analog signal cos a and the digital signal sin ft<M:0>, multiplying them to produce the analog signal Step{cos α*sin ft}. DAC 213 receives the analog signal sin α and the digital signal cos ft<M:0>, multiplying them to produce the analog signal Step{sin α*cos ft}. DAC 223 is used to produce a timing reference signal by multiplying the fixed analog reference voltage sin 90=1 by the digital signal sin ft<M:0> to produce the reference signal Step{sin ft}.

The three “Step” signals are all analog signals, but they have staircase step edges every timed interval of 1/(f_{clock}/K) seconds. These edges, due to the sampled nature of the signals sin ft<M:0> and cos ft <M:0>, are smoothed out so that all analog signals in the system that are presented to the comparators are sufficiently “accurate” representations of sinusoidal waveforms. This smoothing is accomplished by the RC filter blocks which contain a capacitor and may contain a resistor. The resistor works in concert with the output impedance of the DACS. The net resistance of the DAC and the resistor in the RC block combined with the capacitor create a first order filter which sufficiently smooths the three waveforms, labeled cos α*sin ft, sin α*cos ft, and sin ft, which connect to the two comparators.

Comparator 226 produces rising output edges corresponding to the rising zero crossings of the signal sin ft which triggers a START in the Angle Counter in block 721 and is thus referred to as the START comparator. Comparator 206 produces rising output edges corresponding to the rising zero crossings of the signal sin(α−ft) which triggers a STOP in the Angle Counter in block 721 and is thus referred to as the STOP comparator.

The Angle Counter in the DSP block 721 contains a count value at the time of the STOP event which is proportional to the angle α, where a numerical count of Zero corresponds to zero degrees and 360 degrees. The maximum count value corresponds to 360 degrees minus the value of one LSB.

The DSG block 1003 includes a clock which produces a fixed reference square-wave that is used the clock the Angle Counter 721. It also is fed to a Divide-by-k block 301 whose output continuously drives the Cyclical Counter 711 which continuous counts from Zero degrees to 360 degrees-minus LSB, and back to Zero degrees. This clock's output indexes the LUT memory 713 and produces the continuously updated M+1 bit words which are the sin ft <M:0> and the cos ft <M:0> signals that drive the mixer/multipliers in the AXE block 1004.

The BGEn block 1004 provides all analog bias currents and voltages to support operation of the analog blocks.

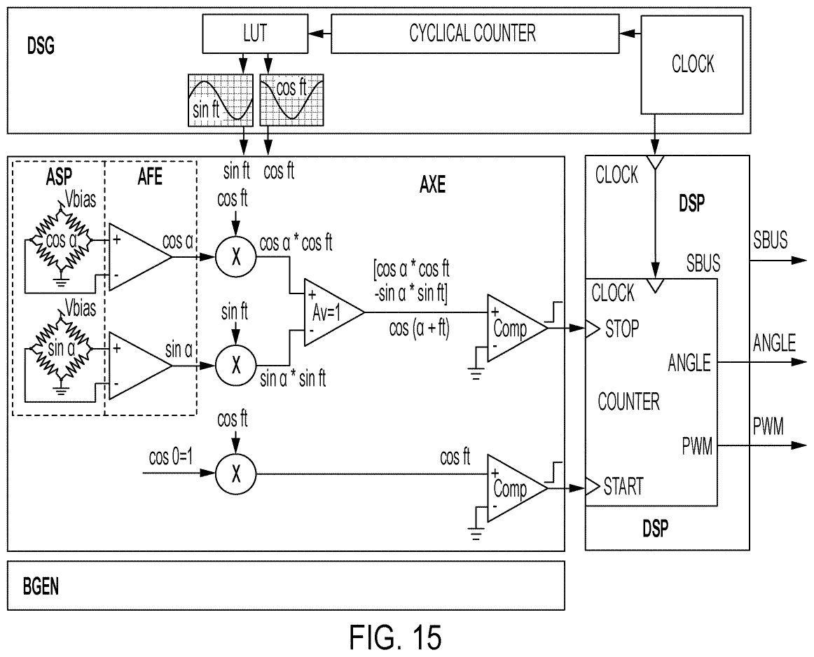

### Architectural Overview of the Implementation of FIG. 15

Although the implementation in FIG. 2 is based on Equation 2A, the implementation in FIG. 15 is based on Equation 2B produces roughly equivalent results if the described angle correction is applied to the architecture. FIG. 15 illustrates the circuitry which implements the trigonometric function in Equation 2B and thus extracts the magnetic field angle.

cos α*cos ft−sin α*sin ft=cos(α+ft) Equation 2B

The signals originate from the ASP (Angle Sensor Pair) in which one sensor produces an analog signal whose voltage is proportional and scaled to cos α, where α is the angle of the magnetic field. The second sensor produces an analog signal whose voltage is proportional and scaled to sin α. Both sensors are biased with a voltage or current which results in the voltage Vbias. These biases originate from the section Bias Generator (BGEN), which allows the differential outputs of each sensor to produce a pair of differential voltages which are each respectively proportional to sin αand cos α, where α is the angle of the ambient magnetic field.

The signal pair sin α and cos α are both processed in the AFE (Analog Front End) to eliminate any offsets, and they are precisely scaled via gain correction such that their amplitudes are precisely matched, and both signals are converted from differential voltages to single-ended voltages.

The Analog eXtraction Engine (AXE) processes these signal pairs to implement Equation 2B as follows. First, the cos α signal is multiplied by cos ft which is a reference cosine of substantially higher frequency than the rotational rate of the magnetic field dα/dt. The continuously cycling signal cos ft originates from the Digital Signal Generator (DSG); likewise, the DSG produces a signal sin ft, which is multiplied by sin α in the AXE. The frequency of both the sine (sin ft) and cosine (cos ft) signals are matched. For each full cycle of sin ft and cos ft, the AXE will render a digital representation of the magnetic field angle α as follows.

The pairwise outputs of the multipliers are (cos α*cos ft) and (sin α*sin ft). These are differenced by the Differencing Amplifier labeled Av=1 to produce the signal (cos α*cos ft)−(sin α*sin ft) which is equivalent to cos(α+ft). A third multiplier mixes the reference signal cos ft*1=cos ft.

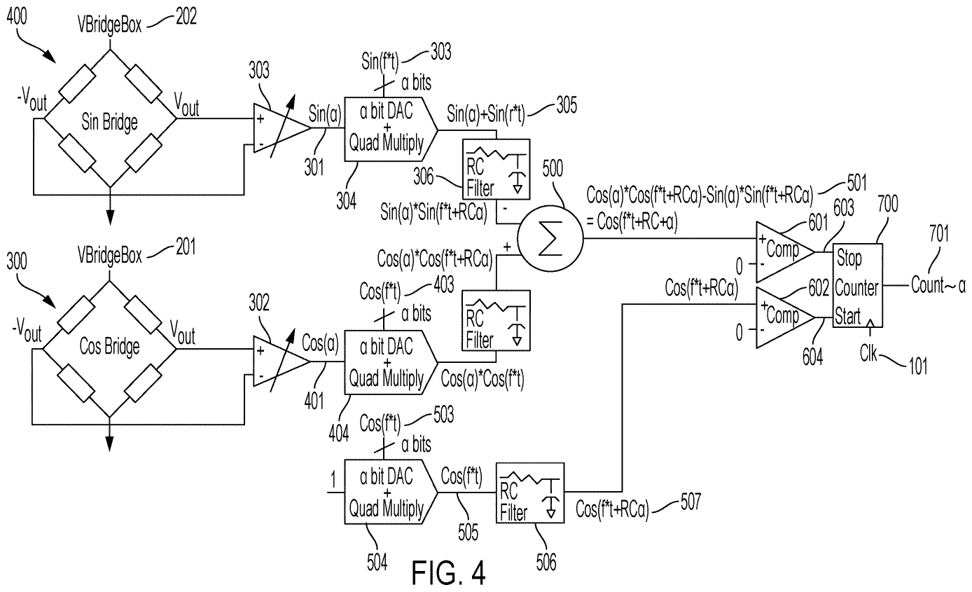

The signals cos(α+ft) and cos ft are pairwise fed into a pair of comparators (each labeled Comp) which will each produce a digital positive edge transition whenever their respective signals experience a positive zero crossing (transition from a negative to a positive value). This occurs because both comparators have their negative terminals connected to a signal ground which is set to the mean value of both the sine and cosine waves. The bottom comparator is a START comparator. The top comparator is a STOP comparator. At the beginning of every extraction cycle, the START comparator sends a START signal to the COUNTER inside the DSP (Digital Signal Processor). To correct the architecture in FIG. 4, either the output angle α is reinterpreted as 360−α, or the COUNTER is changed from a count-up counter to a count-down counter). The counter begins counting up (a count-down architecture is also possible) at the rate of the CLOCK in the DSG. The counter value is saved when it receives a STOP signal from the STOP comparator. At the time of the STOP signal, the COUNTER has a count value which is latched and represents the angle α as follows.

If the counter is implemented as a count-down counter, correcting the error in FIG. 4 and FIG. 15, a zero-value count of the counter, represents an angle α of 0 degrees and by identity 360 degrees. Each bit of the counter represents a small proportional increase in the angle α that has a value as given by Equation 3.

1 LSB in degrees=(1/(Total_Count_Value+1))*360 degrees Equation 3

A full digital count of the counter represents an angle α of approximately 360 degrees (360 degrees minus the value of 1 LSB of the counter).

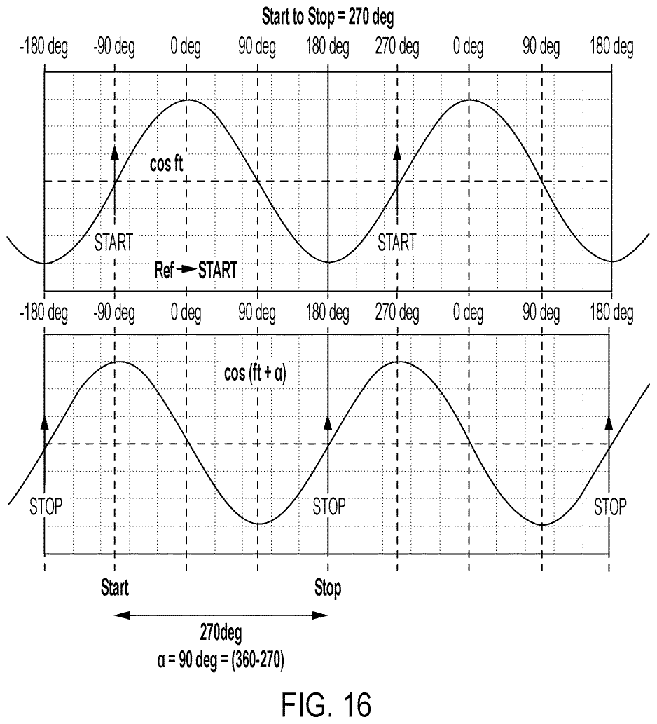

The digital angle that is stored in the counter at the time of the STOP signal is for the architecture in FIG. 15 using an up-counter is (360 degrees−α). (The '728 publication incorrectly identifies that the angle represented and stored in the counter is α.) This is due to the phase relationship between the two signals cos(ft+α) and cos ft as shown in the timing diagram of FIG. 16 which illustrates the result when the angle α is 90 degrees. This occurs because cos ft has a zero crossing which is delayed compared to cos(ft+α). It may be inconvenient to have the angle represented as a complement against 360 degrees (360−α). It is preferred to directly represent the angle as a digital code representing α. One remedy to this issue is to alter the counter so that it counts down from an initial value of 360 degrees. Thus, at the time of the STOP signal, the counter value will directly represent the angle α.

The sections that will implement the angle extraction algorithm are given in FIG. 15 as follows: 1. the Angle Sensor Pair (ASP) produces a set of analog voltages whose magnitudes represent the sine and cosine of the angle of the magnetic field; 2. the Analog Front End (AFE) buffers and amplifies the output of the ASP including any circuits required to reduce offsets and adjust the bias levels of the signals; 3) the Analog eXtraction Engine (AXE) which implements all mixed signal (analog and digital) processing which implements the functional equivalent of Equation 2B and detects the zero-crossing detection event of the signal cos(α+ft) and of a reference signal cos(ft); 4) A Bias Generator (BGEN) that provides voltage and currents references to the ASP, AFE, and AXE, all of which sections contain analog circuitry; 5) a Digital Signal Processor (DSP) or Digital Processor (DP) that converts the zero crossings detected by the AXE into Digital representations of the Magnetic Field Angle which include a periodically updated Angle Value in the form of a digital number and a stream of digital numbers as outputs of a Serial Bus (SBUS).

A zero-crossing event is defined as the moment when the electrical voltage mode sinusoidal waveform transitions through a value of “zero.” This zero value is determined by a reference voltage which is set such that it is precisely (substantially) at the mean level of the sinusoidal waveform. For the above definition, both sine and cosine waveforms are considered sinusoidal. There are two types of zero crossing events considered herein. The first type is defined as an event in which the wave-form crosses zero with a positive slope with the signal values transitioning from a negative to a positive value with respect to the zero-value reference voltage; this transition is referred to as a “positive transition.” The second type is defined as an event in which the wave-form crosses zero with a negative slope with the signal values transitioning from a positive to a negative value with respect to the zero-value reference voltage; this transition is referred to as a “negative transition.”

Additionally, the angle value output from the DP is continually updated via Pulse Width Modulator (PWM) representation of the magnetic field angle. The DSP contains counters and any external interfaces such as serial or parallel bus interfaces. 5] A Clock and Digital Signal Generator (DSG) provides clock signals to the AXE and the DSP and contains counters and Look Up Tables (LUT) used to generate digital signals (sine and cosine of cos ft and sin ft) which are processed by the AXE which are mixed inside the AXE with the analog signals from the sensors (ASP).

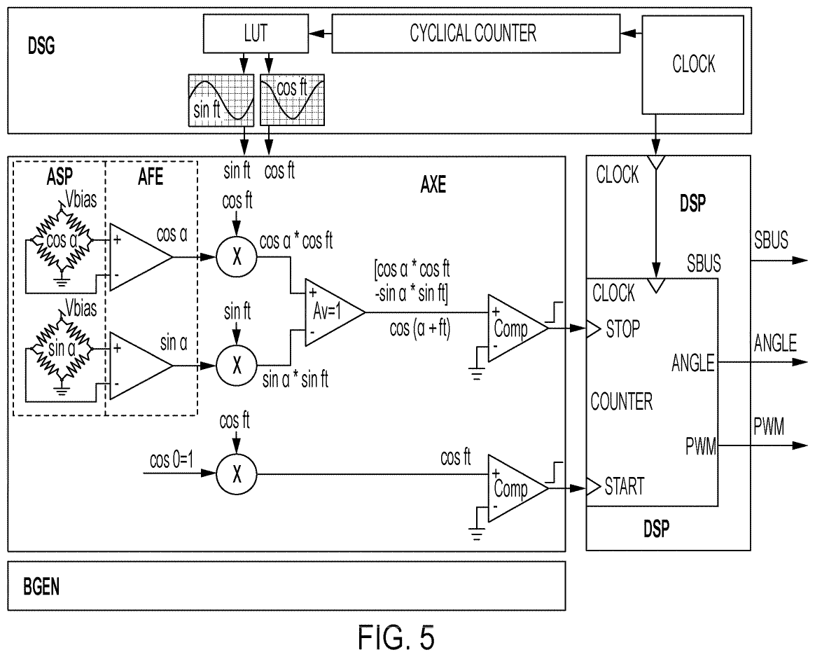

FIG. 8 illustrates an architecture that has at least two significant changes compared to the architecture of FIG. 5. Firstly, the digital signals connecting to the 3 multipliers (203,213,113) have been changed such that the architecture is implementing Equation 2A rather than Equation 2B. Secondly, the differencing amplifier (differential amplifier) labeled “Av=1” has been eliminated. This is accomplished by connecting the STOP comparator directly to the two signals (sin α*cos ft) and (cos α*sin ft), effectively implementing the differencing operation inside the comparator which directly implements a zero-crossing detection of the signal sin(α−ft). This deletion reduces power and area, but more significantly eliminates signal and timing distortions, offsets, and required trimming induced by the differencing amplifier. More significantly, removing the differential amplifier allows the outputs of both comparators which create the START and STOP signals in the Angle Counter to have equivalent delay paths. Leaving the differential amplifier in the architecture would induce an additional delay which induces a delay mismatch (between the START and STOP signal paths) which induces an error in the final value of the Angle Counter. A comparator wired differentially to the top two multipliers has substituted for the precision differential amplifier and the STOP comparator. This substitution is possible because the proposed angle extraction system only relies on the timing of the zero crossings of the sin(ft) and sin(α−ft) waveforms. When these waveforms are not in proximity of the zero crossings, their fidelity and values have no impact on the system performance, because only signals in proximity of the zero crossings need to be preserved.

### Further Technical Considerations and Observations

Referring to FIG. 15, the following observations can be made:

Observation 1) Sinusoidal Signal Generators: The matched frequency of the cos ft and sin ft generators is significantly higher than the maximum magnetic rotational frequency (rate of change) of the magnetic field angle α in the application system. This allows the angle α to be treated as quasi-static. To accomplish this, the change in α must not exceed a quantity equivalent to one bit of the angle counter during a complete cycle of the sin ft and cos ft modulation generators.

Observation 2a) Sinusoidal Signal Distortion and Continuity Requirements: For effective operation of the AXE, the elements need to be operational and accurate only during (or in the temporal vicinity) the zero crossings of the functions that trigger changes in the comparators. Distortion, interruptions, offsets, or even severe interruptions in the waveforms are tolerable as long as the functions recover and converge sufficiently before the temporal vicinity of the zero crossing points. Since the output of the generators and mixer-DACs are discrete time staircase functions, they need to be smoothed out to remove sampling artifacts. In most of the described configurations this is possible using a simple first order filter (RC), but other smoothing methods are possible, including oversampling and averaging the staircase functions to increase the frequency of the analog filter and thus reduce its size and delay.

Observation 2b) Power Saving by Disabling the Signal Generators, DACS, and Comparators when the comparator input signals are not in the temporal vicinity of a zero-crossing event: The above distortion consideration (2a) allows all circuitry in the axe to be disabled when the signals to the comparators are not (or would not be) resulting (experiencing) in zero crossings. Additionally, the sin ft and cos ft signal generators may likewise be disabled, saving power.

Observation 2c) Angle extraction without the requirement running the extraction engine for a full cycle leads to reduced power and faster angle rendering (reduced latency). But, aside from Power Savings, Latency Reduction, and a Higher Rendering Rate: The above observations (2a) (2b) imply that it is possible to only run (activate) the complete system in the AXE and the DSG such that it is only active when it is sweeping past (in the vicinity of) the comparators'zero crossing points, events which only occur twice per operational cycle. This allows for results to be produced in a duration that is much shorter than a fixed full operating cycle. Once an initial single full operating cycle has produced a zero crossing of the STOP comparator, subsequent angle extractions may be repeated without operating continuously and without completing a full operational cycle. Thus, an angle extraction is accomplished by only executing a partial operational cycle in the temporal vicinity (within a cycle) of the last angle rendition. This saves power and results in extremely fast angle extractions with very low latency which should enable in industry leading performance.

Observation 3) Comparator Speed Requirements: High speed comparators respond to zero crossing events with a very short delay time and with a very high edge rate, but require substantially high-power levels and expensive advanced technologies. Utilizing sufficiently high-speed comparators in the implementation of these proposed architectures allows the comparators'delays to be eliminated/reduced as a substantial error source in the rendering of the magnetic angle α, but this is a brute force method. These architectures allow for utilizing slower, more cost-effective comparators. The edge rates of the signals emerging from the analog multipliers labeled “X” (in figures such as FIG. 2) may be very high in the temporal vicinity of the zero-crossings. This might appear to imply that it is a requirement that the comparators be able to operate at edge rates comparable to the incoming signals, requiring similarly high bandwidths. This is not necessarily the case. If the comparators are relatively “slow” in their responses (having significant delays), but as long as both comparators are similar (closely matched) in their output edge rates, offsets, and have low input noise, the induced delays because both the START and STOP comparators will be similar (substantially matched), satisfying the requirements for accurate operation. Referring to FIG. 2, so long as this consideration is the reason a START comparator is required, as opposed to simply and directly starting the Angle Counter at the beginning of each evaluation cycle. For example, if the frequency of operation is low, or the comparators are extremely fast, a START comparator might not be necessary because the difference between the START coming from the comparator versus the numerical value of the zero count=0, would be negligible. These assumptions are unlikely to ever apply since achieving a high-performance angle measuring device will likely always require less comparator delay and lower power (two conflicting parameters). The comparators available will likely have significant delay and thus a pair, one for START and one for STOP will be used in order that the pair delays effectively cancel each-other. The signal path to the STOP comparator output will have significant delays which would limit the system's operational speed without adding matching delays to the START signal. The above consideration, and the realization that slower comparators may produce accurate results in a balanced architecture, as long as certain criteria are met. In the example implementations, the delay paths from the inputs of the multiplying DACs to the outputs of the comparators are substantially matched. This consideration is described below using FIG. 2 as an example. There are three delay paths to the two comparators (206, 226) which substantially match: Path 1 is from the sin ft input to DAC 203 which connects to the RC filter 204 which connects to the negative input of comparator 206. Path 2 is from the cos ft input to DAC 213 which connects to the RC filter 214 which connects to the positive input of comparator 216. Path 3 is from the sin ft input to DAC 223 which connects to RC filter 224 which connects to the positive input of comparator 226. These three paths are matched if the DACs have substantially similar delays and if the RC filters are matched or tuned to match in their delays. Next, the two comparators (206,226) either match, or are tuned to match by adjusting their bias currents. Additionally, the comparators are matched in input offset voltages which can be tuned using DC offset measurements/calibration. Noise is also a consideration. If noise is high enough to affect individual measurements, averaging of multiple measurements can be used to suppress noise related errors. If all of the above criteria are met, it is possible to use comparators that are slow compared to the timing of the system and still obtain accurate measurements. This allows for power reduction and also allows for implementation of the circuits using a less expensive, slower semiconductor process technology.

Observation 4) Rising and Falling Edge Extraction Doubles Angle Extraction Rate: Making use of both rising and falling zero crossings of the comparators allows for a doubling of the angle extraction rate: All operations of the Angle Extraction operation involving the AXE and the DSP that have so far been discussed, only involve operations that are triggered by the rising edges of the START and STOP comparators which correspond to rising zero-crossings of the analog signals at the comparators' inputs, but both comparators also experience falling edges that correspond to the falling edges of the analog signals. Using the falling comparator edges to produce an additional independent set of STARTs and STOPs will result in equivalent operation to the rising edge method, but produces results that are 180 degrees (in terms of the operation cycle defined by the cos ft and sin ft generators) delayed from the results extracted from the rising edges. But significantly, the rising and falling edges of each comparator are always 180 degrees apart or staggered. Thus, exploiting signals using both the rising and falling edges doubles the conversion rate from one conversion per operational cycle, to two conversions per operational cycle with results from rising edges being staggered by 180 degrees from the results from falling edges.

### Implementation Details

In the initial system block diagrams (such as FIG. 2), the signal generators and the multipliers are idealized to just indicate the generators' output sines and cosines at frequencies that are related to the evaluation period T (frequency=1/T), but there are no details of the implementation of these functions. The sine and cosine functions in many prior sensors are generated by periodic rectangular pulses (square waves) which are pairwise separated by a 90 degrees phase difference. These two pulse trains may be processed by a complex high-order filter which are precisely tuned to match the pulse frequency such that they effectively smooth out the sampling steps. This approach is complex and expensive since it requires precision trimming and temperature compensation to maintain the trimming. This approach also limits the frequency of the generator to be precisely fixed, and the generator has a long settling time after startup to allow for the high order filter outputs to settle into a steady state. Also, the area on-chip required to implement these filters is large. In addition, the complex tuned filters consume significant power, whereas the one stage passive RC filter in this implementation requires no power. Single stage RC filters as used in this implementation settle much more quickly, add negligible latency to the first angle rendering, have some flexibility (less sensitivity) as to the frequency of the reference oscillator, and thus allow for a system in which the reference oscillators may be arbitrability paused and even shifted in their phases. This flexibility allows for a higher update rate than a conventional continuously operating oscillator.

The various implementations described herein use a hybrid analog/digital approach to generate the modulating sinusoidal waveforms which avoids the requirement of a high-order complex bandpass filter. For example, the implementations in FIG. 2 and FIG. 10 utilize a hybrid analog and digital approach to replace the above-mentioned complex filters wherein a digital approximation of the sine and cosine reference waveforms are each generated as a periodic sequence of digital numbers utilizing a cyclical counter (711 or 741), which repeatedly cycles at the time period T. The cyclical counter (713) generates a count which addresses a LUT (713), the Look Up Table. The LUT is a memory array that stores both a sine and cosine waveform in digital format. As the cyclical counter cycles from zero to max_count, a full sine and cosine wave are pairwise output in digital form from the LUT. Each of the pairwise digital sequences, one sine and one cosine are sent to multiplying DACs (203,213,223), represented by the symbol marked “X”. Each Multiplying DAC has an analog input and a digital input. The digital input is changed and updated at the rate of f_{clock}/K. The output of each multiplying DAC is comprised of the analog input multiplied or scaled by the digital input number producing a mixed output. Each mixed output updates at the rate f_{clock}/K. For each update of the mixed output, its value is the value of the analog sinusoidal function, scaled by the present digital value, implementing a multiplication function. Both outputs of both multipliers are roughly sinusoidal in shape, but they have a staircase (sampled) appearance since the sinusoidal output is being updated every 1/(f_{clock}/K) seconds. For accurate operation, these two bumpy staircase-like waveforms need to be smoothed out to approximate smooth accurate sinusoids. This may be accomplished inexpensively and compactly by placing a simple first order RC filter (204,214, 224) in series with each of the DAC outputs. This filter requires little tuning and is much easier to implement in comparison to the complex filters implemented in prior sensors. In FIG. 2, the filtered signals are connected to the comparator (206). There are a series of delays in both signal paths after the digital code is updated. The DAC has a delay, as does the RC filter. Next the comparator has a delay. To accurately resolve the angle, the total series delays from the signal sources to the outputs of the START and STOP comparators are closely matched. Thus, the reference START comparator (226) has its signal generated by a DAC (223) which is multiplying a fixed unity reference voltage labeled sin 90=1, against the signal sin ft<M:0>. This product is labeled Step{sin ft}, which is jagged and needs to be filtered by the RC filter block (224) to produce a substantially smooth signal sin ft which is compared to the signal-ground voltage reference level by the comparator (226). Thus, both comparators have similar delays in their signal paths, preserving timing accuracy.

In the implementation outlined in FIG. 2 (and all implementations that are illustrated), all smoothing of the signals from the DACs is done with a simple small analog filter. Alternatively, or additionally, smoothing may be accomplished in the digital domain by up-sampling the digital data and using, for example, a four-tap interpolation filter (FIR). This will substantially smooth the steps in the analog waveforms and reduce the required analog filtering. The DAC in FIG. 2 (and all implementation that are illustrated) is an N+1 bit DAC, operating at a conversion rate of f_{clock}/K. Changing to up-sampling and interpolation, requires the DAC to operate at a conversion rate of 4*f_{clock}/K and changes it from an N+1 bit DAC to an N+3 bit DAC since the interpolation may effectively increase the bit depth and the step to step timing resolution, depending on the details of the up-sampling implementation.

### How Comparator and Filter Implementation and Speed Impacts the Architecture

The speed and offset of the comparators affect the performance of the system. Comparator-speed may be simply defined here as the amount of time it takes for a comparator to produce a rising or falling transition (from logic Lo to logic HI or from logic HI to logic LO) after the differential input to the comparator is presented with an analog zero crossing. The offset of the comparator is also critical since the exact value of the offset can either delay or advance the before-mentioned transition. Assume that the offset is zero for the following considerations. Comparator offsets can effectively be nulled-out using comparator architectures known as chopper stabilized comparators. Alternatively, comparator offsets may be trimmed out to very low values such that they have no substantial impact on timing. Alternatively, a pair of comparators may be trimmed to have matching non-zero offsets and as a result have substantially matching delays.

For a given system specification, the required comparator speed depends on the following considerations. The faster the maximum allowable rotational speed, the faster the comparator must transition. The more precise the angle resolution, the faster the comparator must transition. As comparator transition speed increases, so does the required power consumption increase. Very high-speed comparators require lots of power and may also require a high-speed semiconductor process which adds to chip cost.

To develop system specifications, especially for comparators, the foremost specification to consider is the time allowed to render an angle. If this specification is at 8 ms to render an angle result, then the cosine and sine reference generators produce a full 360 degree cycle every 8 μs. An example of comparator requirements: if a system is to have 12 bits of resolution per 360 degrees, it must resolve to 360/4096 degrees which is 0.879 degrees per step. Thus, dividing the 8 μs cycle into 2\hat{ }12 pieces gives 1.953 ns per step. To be maintain accuracy, the comparator must transition in at least ½ of a step or ~0.04 degrees or 0.976 ns. If the rotation speed is 100K rpm or at 1.666 KHz. This is 360 degrees in 0.6 msec. The time in which a 0.04-degree rotation occurs is (0.6 ms/360)*0.04=0.66 μS.

A comparator that can transition in 0.976 ns is a very high-speed comparator. Alternatively, a slower comparator that has a transition time significantly longer than 0.976 ns is possible to be used if certain conditions are met. This is conditional that the comparator transition time has a consistent delay from cycle to cycle and that the pair of comparators (206 and 226 in FIG. 2 are well matched for delays. A comparator with a consistent delay which is low in noise induced variations, will render an accurate result if the START and STOP comparators are matched in offsets and biasing and also low in noise.

If the comparators are noisy enough to impact the accuracy of the results, a multiplicity of sequential results may be averaged to improve the accuracy by rejecting the noise through averaging. This improvement can only be applied to relatively static magnetic angles where precision is more important. With dynamically changing angles, averaging is not possible, but less accuracy is tolerable.

An example of a typical high performance design goal is given as follows. The maximum spin rate for the measured magnetic field is limited to 100K RPM. Each evaluation cycle is given as 8 μs. During each evaluation cycle of 8 μs, the reference generator's sine and cosine signals each complete a full 360-degree cycle.

The sine and cosine reference generator outputs are digital signals, when they are mixed as inputs to the multiplying DACs (203, 213, and 223), the analog outputs of each multiplying DAC is a staircase function that simulates or approximates a sinusoidal waveform. The RC filters (204, 214, 224) are tuned to smooth out the staircase artifact, resulting in a substantially smooth continuous sinusoidal waveforms. The Comparators (206 & 226) might be required to be very fast to accurately locate the zero crossings of the fast edged waveforms, but they may actually contribute a substantial but tolerable delay in their transitions around the zero crossing, so long as the delays and offsets from both comparators are well matched.

FIG. 2 illustrates an exemplary implementation the overall architecture for the angle sensor system. The RC filters (204, 214, and 224) are used to smooth the step-like characteristic of the multiplying DACs' (203, 213, and 223) outputs. It is essential that they are sufficiently matched to prevent any substantial delay skews at the three filter outputs. (The quantitative requirements for maximum allowable delay skews are covered above.) These filters are trimmed to match each other (in filter frequency and propagation delay time) at the time of manufacturing. They can be subject to thermal drift on the condition that all three filters may thermally drift but they all experience drifts that substantially track each other. As long as they drift together (in a likewise value) with a common amount of delay, the system performance is unimpacted. Likewise, comparators 206 and 226 have delays that are tightly matched. If all of the above-mentioned comparator plus filter delays track well within their group, then any delay to the START signal in 721 and to the STOP signal in 721 will match and have no impact on the value of the Angle Counter element 721 at the end of each evaluation cycle.

This clarifies a property of the behavior of the AXE (1001). If the delays (response times) of the comparators are made to be extremely fast, the system is able to accurately capture the magnetic angle measurements at high rotational rates. This requires very fast comparators which require large amounts of power and fast technologies to implement the system. Alternatively, if the comparators are allowed to operate more slowly, implementation is easier, the IC technology is less expensive and system power is reduced. To accomplish this simplification, the comparators need to be tightly trimmed matching their delays and offsets. Under these conditions the START and STOP signals to the Angle Counter (721). Will be substantially matched and not impact the rendered angle count.

An alternative implementation, but unlikely, method would be possible if it is ensured that the RC filter delays are low enough not to impact the Counter values, and that the comparator 206 is extremely fast. Under these conditions, components elements 223, 224, and 226 may be removed and the START signal may originate directly from the Cyclical Counter (711) using a digital comparison between the counter value and the count value at which the sin ft value coming out of the LUT (713) is at ZERO. This reduces components in the system at the cost of high power required to operate the very fast STOP comparator 206. In some implementations, the architecture in FIG. 2 can use lower power comparators while trimming the comparator and the filter delays. Additionally, delays created in the digital domain by the multiplying DACs are predictable and may be accurately considered in the system since they are directly linked to the system clock frequency.

The above discussion is also applicable to the most of systems illustrated. The only change from these illustrated architectures is that the comparator connected to the START signal may be eliminated and the START signal is directly connected to a digital comparator originating from the CLOCK block which triggers a transition synchronous to when the cosine generator would produce a positive zero crossing at 270 degrees. This is unlikely to work well at high frequencies since there are still un-equalized delays through the multiplying DACS that are still in the path of the STOP signal but are no longer present in the path of the STOP signal. However, as mentioned above, these DAC related delays are predominately digital in nature and may be accurately accounted for and compensated in the digital domain.

The description of the basic building blocks for an angle extraction mechanism described herein is generally applicable to all illustrated implementations (although the trigonometric identity employed will change the specific signal names of sin versus cos: an Analog Front End (AFE) that amplifies and normalizes (scales) the magnetic bridge signals, an extraction engine that rapidly determines the angle of the magnetic field using both analog and digital components (mixed signal processing), and a completely digital section which processes the digital outputs from the previous sections and formats them to various digital standards.

The Angle eXtraction Engine (AXE) comprises an Analog Front End (AFE) which sends START and STOP signals to a PWM/Counter block which contains counters and registers that can store START and STOP values and count clock pulses between START and STOP events to determine the value of the magnetic angle α. The START and STOP pulses originate from the two comparators. (PWM is an abbreviation for a Pulse Width Modulator.) One comparator detects the zero crossing signals of a reference signal generator the generates cos ft (FIG. 5) or sin ft (FIG. 2); the other comparator detects zero crossings of the signal cos(ft+α) FIG. 5 or as given in the above Equation 2B as illustrated in FIG. 5 or, alternatively, a zero crossing of the signal sin(ft−α) as given in Equation. 2A as illustrated in FIG. 2. The signals from the two comparator are labeled as STARTs and STOPs because they trigger starts and stops in the counter whose final value is either proportional to the angle of the magnetic field α in FIG. 2 or proportional to 360 degrees−α in FIG. 5: the ratio of the stopped counter value, compared to the full count value gives the angle α as a percentage of 360 degrees or 360−α in the case of FIG. 5. FIG. 9 illustrates the waveforms and signals in a cycle that is used in the basic operating mode. A complete rendering or operational cycle is defined as the clocked interval of the angle counter from one STOP signal to the next STOP signal or the interval from one START signal to the next START signal. This count is a virtual count since the angle counter only normally counts from a START to a STOP, a partial count. If the ANGLE is a full count of 360 degrees minus one bit, then the count time of the angle counter matches the time of a full cycle. Alternatively, a full cycle may be defined as the time it takes for the cyclical counter to count through an entire digital cycle, starting at some value and returning to that same value.

The AXE also includes a Digital Signal Generator Block DSG) which generates multi-bit digital representations of sine and cosine signals. The AXE (AFE plus Counters and Registers) can operate in several modes or methods which make tradeoffs between angle rendition speed (or update rate), angle accuracy, internal and external noise mitigation, and power savings. A digital processor (such as a DSP, not shown) evaluates signal timing from the analog AXE and formats the digital outputs from the AXE translating them into various standard and customized formats. Supported output formats include, but are not limited to PWM (Pulse-Width Modulation), UVW, ABZ, and ABI. The raw digital angle codes may also be transmitted through a serial or parallel bus or dedicated signal lines. The DSP is also capable of averaging successive angle renditions for cases in which the angle is substantially static to improve accuracy via interpolation and noise reduction, or in the case of constant RPM states it can improve angle αccuracy via interpolation and reduce latency by projecting the current instantaneous angle value.

As above described, the AXE operates in what is referred to as a “cycle.” Each cycle is a complete period of the internally generated sine and cosine signals which correspond to the cos ft and sin ft components of Equation 2B.

cos α*cos ft−sin α*sin ft=cos(α+ft) Equation 2B

In the Standard Mode operating method, one value of angle α is rendered (or generated) per cycle. In the Double Data Mode, two values of angle α are rendered per cycle. In the Incremental Update Mode only a partial operating cycle is required to render an angle and thus update rates are much faster. In the Virtual Stop/Start Mode, complete operating cycles are utilized to render multiple START and multiple STOP count values. Multiple START count values may be averaged to remove noise from the START values. These START values may be compared to STOP values that are either single STOP values or a multiplicity of STOP values, which may be averaged to improve accuracy if the angle is static. If the rotational velocity is constant, then multiple STOP values may be accumulated and interpolated to predictively result in zero latency updates of the angle. The duration of a complete cycle is selectable according to overall system requirements that are external to the present implementation. The AXE may have multiplicity of implemented operational modes which allow for increasingly higher update rates: Standard Mode, Double Data Mode, Virtual STOP/START Modes, and Incremental Mode. Standard Mode delivers an angle output for each operational cycle of the reference generator based on the timing difference between rising edges of STOPs and STARTs. The Double Data Mode provides two angle outputs for each operational cycle of the reference generator using the same mechanism as Standard Mode but adds a separate evaluation of the falling edges (in addition to the rising edges) of the STOPs and STARTs. The Incremental Angle Mode uses the same sinusoidal frequency as the full cycle reference generator previously described, but only produces partial sub-cycle bursts of the sinusoidal waves around the expected zero crossings providing angle renditions in a fraction of the original operating cycle time, enabling the AFE and Signal Generators only in temporal proximity to the temporal vicinity of the previous STARTs and STOPs with an added margin to allow for analog settling and angle changes. The generator produces the sine and cosine modulating waveforms for only a partial interval that margins around the last angle solution as shown in waveform FIG. 11 and indicated by a bolded section of the waveform labeled as “retracing”.

The implementation illustrated in FIG. 2 simplifies the analog architecture by eliminating the differential amplifier stages from FIG. 5 and FIG. 15 and thus reducing the amount of digital calibration. The architectural improvements allow for more accurate and faster angle detection by reducing the transition speed (time) requirements for high-speed comparators because both comparators will introduce similar delays and thus have little or no net impact on the calculated angle. Averaging and post processing options suppress noise and improve accuracy for precision operation.

In the following figures, there are references to REF→START and REF→STOP.

REF→START refers to architectures in which zero crossings of signals from the reference generator is connected to the START comparator which triggers a START in the angle counter.

REF→STOP refers to architectures in which zero crossings of signals from the reference generator is connected to the STOP comparator which triggers a STOP in the angle counter.

FIG. 1: Idealized diagram of sine & cosine magnetic sensors with axes indicating the relationship between sin α, cos α, and the magnetic angle α on a unit circle.

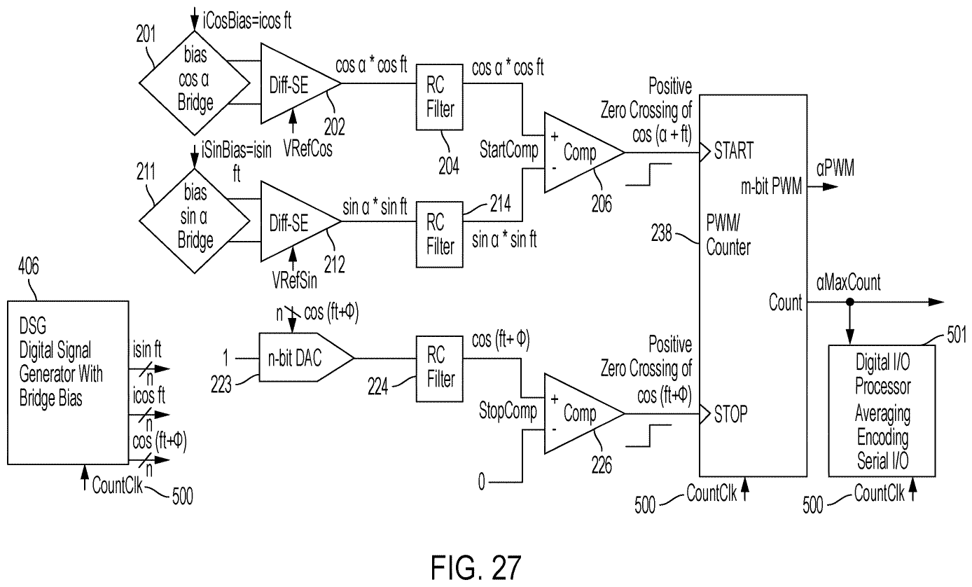

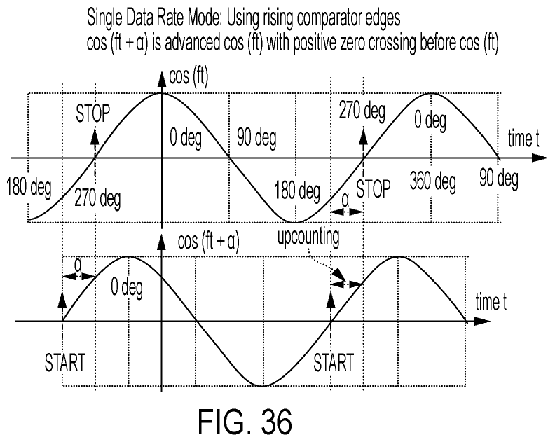

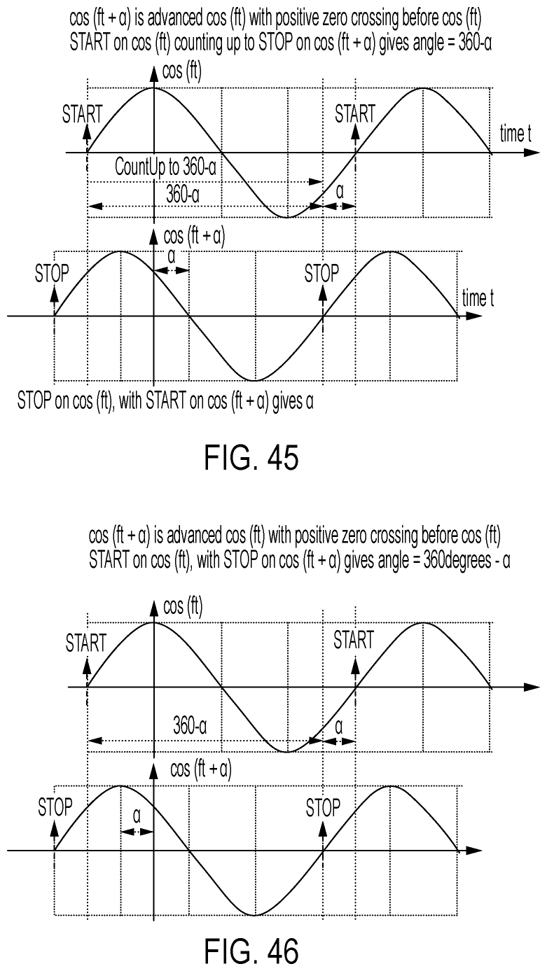

FIG. 5 and FIG. 15: Architecture of an angle extraction system using the trigonometric identity in EQ. 2B: cos α*cos ft−sin α*sin ft=cos(α+ft). It is noteworthy that it contains a differential to single ended unity gain amplifier (labelled Av=1) following the multipliers, and although the output is labeled “ANGLE” the output value is actually (360−α) degrees. FIG. 45 illustrates the Timing of the STARTs and STOPs which define the extraction of the angle as (360−α) degrees. FIG. 45 also applies to the architectures illustrated in FIGS. 5, 15, 18, 20, and 27. FIG. 36 illustrates the timing if the START and STOP connections are swapped, as illustrated in the architecture in FIG. 34 so that the angle α is directly rendered.

FIG. 4: Architectural diagram from prior art patent application. With and FIG. 5 and FIG. 15 being a re-drawing of FIG. 4.

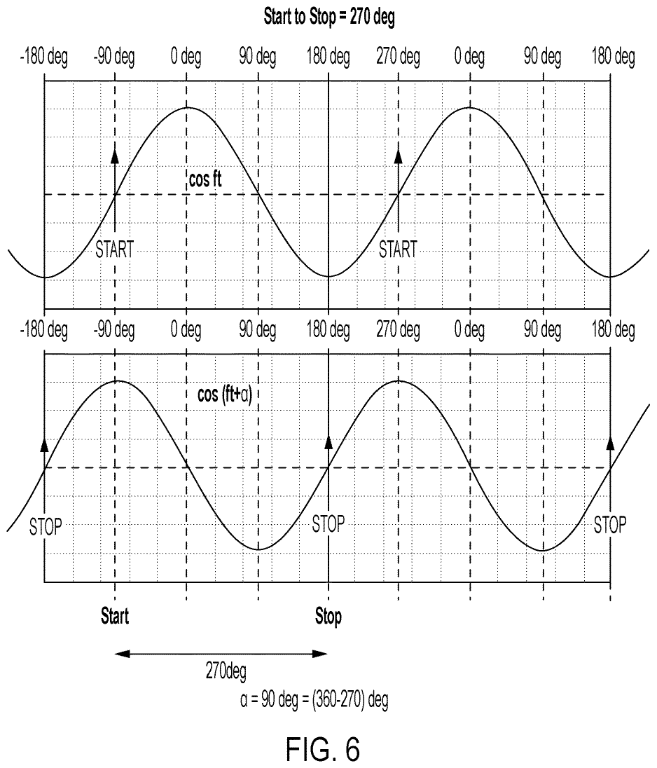

FIG. 6: Timing diagram of the relationship between the signals driving the START and STOP comparators in the architecture illustrated in FIG. 5 and FIG. 15 in which angle α=270 degrees.

FIG. 3: Timing diagram of the relationship between the signals driving the START and STOP comparators in the architecture illustrated in FIG. 2.

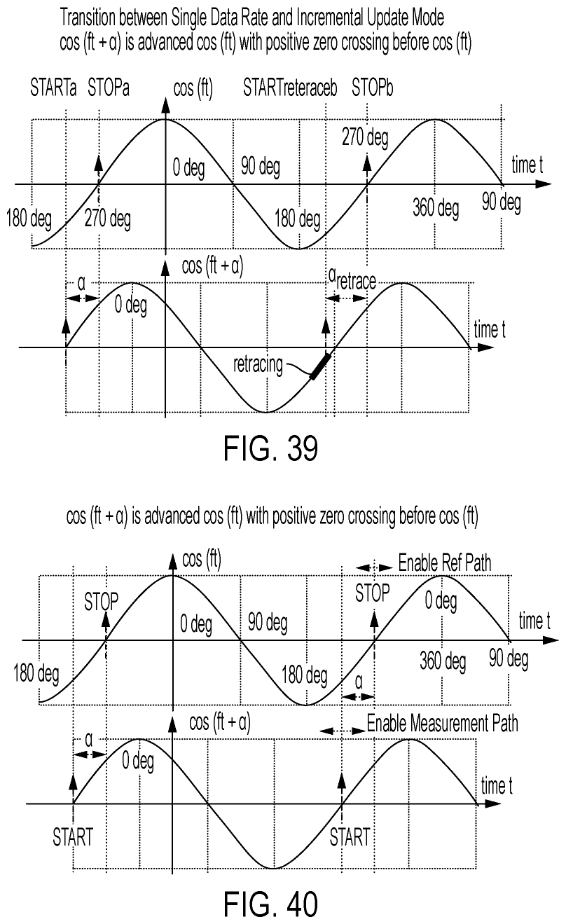

FIG. 39 and FIG. 40 illustrate the waveform timing diagram for an example of both the Incremental Update Method and the Single Data Rate Count Down Method using Virtualized STARTs and STOPs (with swapped START and STOP connections to the PWM/Counter such that START sources from the cos(ft) comparator and STOP sources from the cos(ft+α) comparator). The PWM/Counter is operated in a count-down mode. The Incremental Update Count-Down Method with Virtualized STARTs and STOPs is also represented by this waveform diagram. The bold overlays on the sinusoidal waveforms indicate temporal regions in the circuitry that are active. In the duration between these highlighted times, the only circuit that is required to be active is a master maintenance counter which coordinates and presets the counters in the DSG and the down-counter. Also, it is the Waveform diagram for an example of the Incremental Update Method with swapped START and STOP connections to the PWM/Counter with START sourcing from the cos(ft) comparator and STOP sourcing from the cos(ft+α) comparator. The PWM/Counter is operated in a count-down mode. Ref→START.

FIG. 5 and FIG. 15 are reconfigurations of the block diagram shown in FIG. 4. FIG. 4 has the original block numbers as given in the '728 publication, which is also FIG. 4 within that document. All the reference numbers that follow in subsequent figures are referring exclusively to the present application. FIG. 2 is an evolution from FIG. 5 and FIG. 15 but with the significant architectural change that the differential amp that is connected to both multiplying signal DACs has been eliminated. Instead, the outputs of the two signal DACs are directly connected to the STOP comparator. This change reduces power and improves accuracy by removing the distortion and offsets of a differential amplifier stage. The waveforms between the DACs and the Filters are stepped waves. These waveforms are not considered to be continuous functions until they have been filtered by the RC Filters (204, 214, 224). The up-counter is a synchronous counter in which all bits are simultaneously (synchronously) updated. The up-counter may be used in a continuous mode in which it naturally overflows and returns to zero after a full count. This overflow may be registered by an overflow bit. A simple non-synchronous ripple counter would add unacceptable timing errors into the DAC waveforms. The up-counter (237) latches the STARTS and STOPS on the rising edges of the comparators (206, 226). After the rising edge of comparator 206, the counter is reset to zero and begins counting up. The rising edge of comparator (226) stops the count and the angle α is recorded and latched as the difference between START and STOP COUNTS. The angle α is recorded as a P-bit number that represents the angle of the magnetic field. The number of bits P is usually 12 or 14, matching the specified required angle precision. The clock ClkCount can be a radix 2 multiple of the clocks used to generate the digital sine and cosine functions which are n-bit digital inputs to the DACs whose clock is a radix 2 division of the ClkCount clock.

FIG. 5 and FIG. 15 take the differential output of the magnetic sine sensor (211) of angle α (sin α), convert it to a single-ended signal (212), and multiply it by a digital sin(ft) (213), which produces a stair-case analog function. The RC anti-aliasing filter (214) smooths out the quantization steps. The equivalent processing is applied to the magnetic cosine α function (201, 202, 203, 204). The two modulated functions are differenced by block 205 to produce the function: cos α*cos ft−sin α*sin ft=cos(α+ft). On a separate signal path, a copy of the cosine generator is multiplied by a unity reference voltage connected to block 223 and filtered by block 224 to produce cos(ft). The functions cos(α+ft) and cos(ft) are each respectively compared to a zero reference by comparator blocks 206 and 226 which respectively produce the START and STOP signals for the up counter (block 237), when each of the signals cross zero on their respective rising edges. Note that the START and STOP functions are incorrectly indicated in this drawing, and in the original patent filing. As illustrated in FIG. 2, the result will not be angle α as indicated but 360 degrees−α. START and STOP need to be swapped. A correct START is produced by the cos(α+ft), and a correct STOP is produced by the cos(ft) function. A full count of the up-counter (237) corresponds to an angle α=360 degrees, (partial-counts/full-count)*360 degrees gives the angle α as a digital number of P bits. Essentially the delay between the rising zero crossing of the comparator for cos(α+ft) and the rising zero crossing of the comparator for cos(ft) is proportional to the angle α. This delay is counted in time as measured by the difference of digital value of the up-counter at the time of the STOP signal compared to the value of the counter at the time of the START signal. Angle α is given as: Angle α=360 degrees*(CountStart−CountStop)/FullCount.

FIG. 8 corrects the START and STOP errors and deletes some components to improve the accuracy by removing the delay skew, offset, and distortions of the differencing amp (205) from FIG. 5 and FIG. 15 (with the STOP signal originating from the reference path). It also changes the architecture to be based on Equation 2A, rather than Equation 2B. Removing the differencing amp equalizes the delays of all 3 sinusoidal signal paths, removing an error source, an extra delay, while reducing power consumption and area. The differencing amp (205) is replaced by a comparator which instead of comparing the output of the differencing amp against zero, now compares the two signals from the DAC filters' (204, 214) outputs against each-other. This result is mathematically equivalent to the results in FIG. 5, but the implementation of FIG. 8 saves area, power, and eliminates the extra delay of the diff amp, equalizing the delay times in all three sinusoidal signal paths. It should also be noted that the differential input signals and the slew rates to both comparators at the zero crossings is substantially identical. This allows for substantially uniform delays from both comparators and potentially relaxes the comparators' transition speed requirements. Since delays from the zero crossings to the transitions in the comparator output states will be substantially the same, longer delays will not substantially impact the counted value of αMaxCount at the up-counter output.

The PWM/Counter (238) in FIG. 2 and most implementations enhances the functionality of FIG. 4 by adding a PWM output whose duty cycle is proportional to the angle α. Note that the angle of the data in the PWM/Counter does not match the angle of the digital oscillators. It is counting from the START event to the STOP event. Since the START to STOP interval is proportional to the angle α, so is the duty cycle of the PWM which represents an angle that is a percentage of the 360-degree cycle. The PWM is in a HIGH state from the rising edge of START to the rising edge of STOP. A complementary PWM could be utilized that has the opposite polarity.

The system clocks can be organized in ratios of Radix 2, which results in convenient and efficient clock dividers. The DAC clock that generates the digital sine and cosine waves could be the same clock as the clock driving the up-counter block (237, 238), but this would force the look up table (LUT) that generates the sinusoidal waves to be very large, consuming a large amount of on-chip real estate. For every reduction of the DAC clocks by a factor of 2, the size of the LUT is halved. Also, this reduces the clock rate to the generators and reduces the speed requirements of the multiplying DAC, thus reducing power and reducing the size of the multiplying DACs. The lower the clock rate to the DACs, the larger the RC filter required. An optimum compromise is possible for each chosen semiconductor technology.

FIG. 18 is the equivalent to FIG. 17, except that the START and STOP have been swapped such that the zero crossing of the reference cos ft is triggering the START at the beginning of the cycle. (Here the START signal is originating from the reference path and many figures that share this property are marked “Ref→START”). In this implementation, instead of producing the angle α, the output is 360 degrees−α. Also, the PWM gets inverted since this mode places the START at the beginning of the generator cycle. Thus, since the signal generator always begins a cycle at a count of ZERO, the zero crossing of the reference comparator (226) will always occur slightly after the ZERO count. Since the registered value of the START is now slightly greater than ZERO. It is now possible to average several ZERO crossings and average out noise. The stored average can be used as a virtual START.

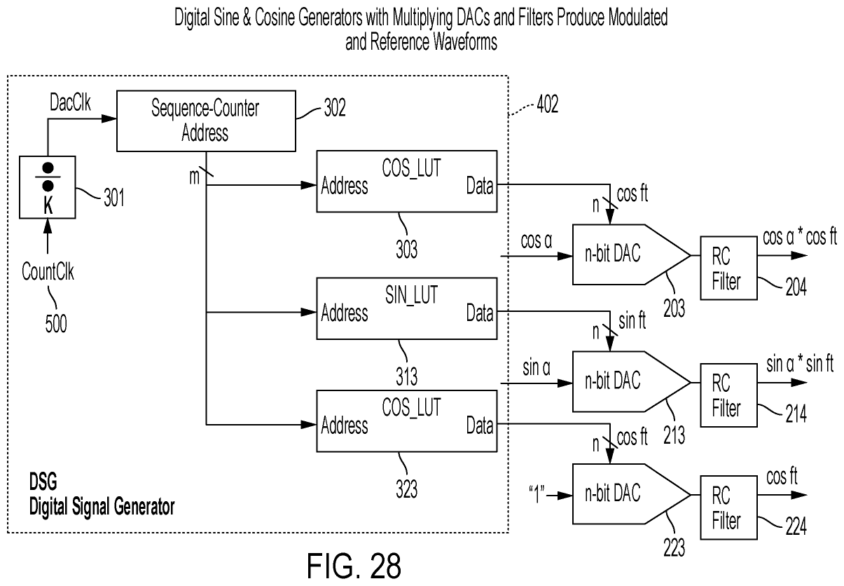

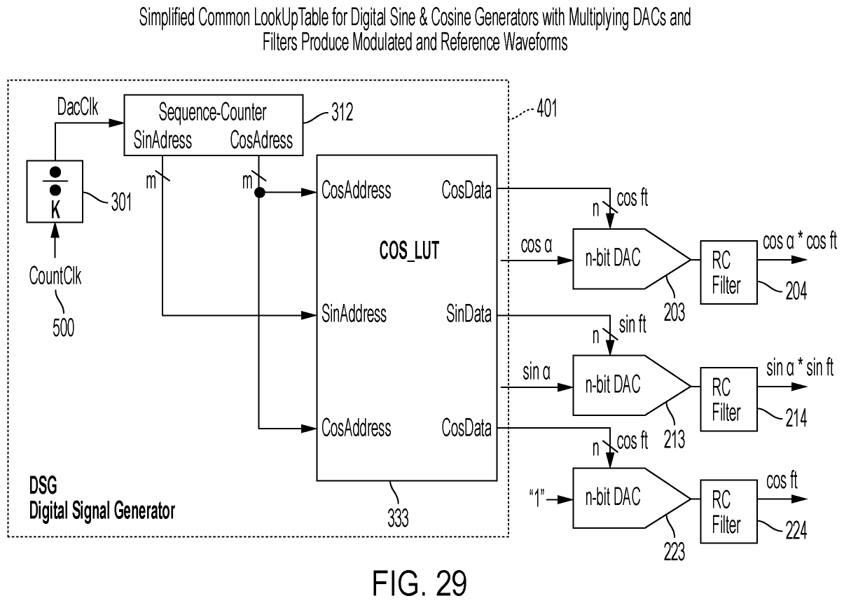

The three DACs in in all figures of the main architecture are fed by digital sine and cosine generators. The sine and cosine generators are represented in FIG. 28 and FIG. 29. The implementation in FIG. 28. Has three separate LookUpTables (303, 313, 323) (LUT), for each of the DACs. The implementation in FIG. 2, FIG. 5, and FIG. 15. Shows a reduced implementation where one LUT (343) is shared by the three signal generators. This is feasible since the data for a sine and a cosine waveform are identical except for the phase/timing. Also, the two digital cosine waveforms for the cosine reference and the cosine signal path are identical in most possible implementations. Essentially, the same LUT is used to generate two different output data signals. To do this, there needs to be two independent address inputs to the LUT; these inputs need to be added to the LUT and would be labeled SinAddress and CosAddress which respectively index and produce the outputs SinData and Cos Data. There are thus two independent memory readers for a common LUT and two independent index generators.

The LUT only needs to hold the first 180 degrees of a cosine function. To create a complete cosine wave, the pointer to the LUT starts at 0 degrees, increments forward to 180 degrees, and then decrements backward to zero degrees. To create a complete sine wave, the pointer to the LUT starts at 90 degrees, decrements down to 0 degrees, increments from 0 degrees to 180 degrees and then decrements back to 90 degrees. In each case, for the sine and the cosine, the described cycle patterns are repeated indefinitely. In some implementations, only one quarter of a cosine wave is stored the other three quarters are derived from the first quarter cycle but this would involve the implementation of a sign bit and manipulating the offset of the waveform. A mathematical manipulation of the binary data representing the waveform can produce all four quadrants of a sine or cosine waveform, while reducing the LUT size by a factor of four.

In FIG. 29 the LUT provides the digital data to the three Multiplying DACs. Note that the Sequence-Counter (312) not only provides two distinct and independent outputs (Sine and Cosine), but additionally, the numerical sequences used to index the lookup table can be tailored. The default sequence might be a full scan from 0 degrees to 360 degrees, but this is inefficient since there is a 2× redundancy in both the Sine and Cosine data. For the Cosine generation, it is possible to start at 0 degrees advance to 180 degrees and then decrement from 180 degrees back down to 0 degrees to represent a full 360-degree cycle. Similarly, a Sine generation can start at 180 degrees, decrement down to 90-degrees and increment back up to 180-degree, then increment to 270-degrees and decrement back down to 180-degrees. The analog sine and cosine signals sin α and cos α, are connected as analog references to two of the DACs (203, 213), which then multiply the analog signals by the digital signals to produce the two multiplied analog outputs. The reference DAC (223) has its reference connected to a constant unity voltage signal called “1” which has the same analog value as the peaks of the sine and cosine analog signals. This DAC outputs a refence cos(ft) that is always at full-scale since it is not modulated by the angle signal.

Note that all three DACS are outputting analog staircases which are stepped representations of the waveforms. These three waveforms can be low-bit representations of the required digital waveforms. To yield angle accuracies of 0.1 degrees, a 12-bit DAC with 12-bits (4096) of samples in each cycle of the sin α*sin(ft) and cos α*cos(ft) waveforms is ideally required. To use DACs with less samples and less bit depth, adding the RC filters to each output, smooths out the staircase artifacts and results in a smooth analog waveform that meets the 12-bit accuracy requirements. For example, this is possible using only 8-bit data and only 8-bits of samples per cycle. Optimizing the number of samples per cycle and the bit depth is possible for a variety of values. Running the DACs at the full 12-bit data and 2¹² bit samples/cycle requires a much larger LUT and a faster/higher resolution DAC.

Essentially, the RC filter is interpolating between the sparse data points to effectively increase the resolution in amplitude and time. Alternative methods of interpolation are possible. One possible interpolation method is to over-sample the data and add on an FIR filter in the digital domain that window averages between the two actual digital data points to produce a near linear interpolation that is then fed to faster and higher resolution DACs. This way the LUT is kept small, but the DAC needs to be much higher resolution and higher speed. The RC filter is proportionally reduced in area since the filtering frequency is increased by the factor of increase in frequency. For a change from an 8-bit cycle to a 12-bit cycle, the DAC output runs at factor of 16 higher in frequency. Thus, the anti-aliasing RC filter can be reduced by a factor 16 in area.

Choosing between the above referenced oversampling methods, a full bit implementation of the LUT and DACs, and a selection of the bit depth and width when using either interpolation method is likely to be influenced by the choice and properties of semiconductor manufacturing process.

FIG. 30 is nearly equivalent to the Sine and Cosine Generators in FIG. 29, except that the Cosine generator that produces cos ft is made independent (decoupled) from the cosine generator that generates the digital cosine function used to produce cos α*cos ft. This implementation allows for the cos ft reference path to operate out of sync with respect to the cos(α+ft) path. This flexibility allows the Incremental Update Mode to operate with multiple fast updates of the angle α while simultaneously and independently updating the value of the STOP. This architecture decouples the STARTs from the STOPs allowing both to function asynchronously. This new architecture can support the Incremental Update Mode with Virtual STOPS and STARTs, improving accuracy over operating the incremental mode with STARTs and STOPs that are generated as single events for each incremental acquisition cycle.

FIG. 33 adds details and functions to the PWM/Counter (248) that support power reduction modes and details the operational properties of the block (with the STOP signal originating from the reference path). The counter value of the STOP edge is independent of the angle α, and only has a minor dependency on temperature due to temperature sensitivity of the comparators. Thus, it is predictable that the counter value of the STOP edge will be substantially consistent from one cycle to the next (ignoring noise) at a given temperature. Thus, we may store a value of STOP in memory and use it to calculate the value of a and to generate the PWM (here the PWM is not directly coupled to the START and STOP events and is separately generated. In this mode, it is only necessary to update STOP frequently enough to smoothly track temperature changes which will likely impact the value of STOP. Values of STOP will typically be close to but above 270 degrees and vary with temperature due to variations in the comparator (226) delay. To help understand the relationship between the values of the PWM/counter versus the values of the reference cos(ft) generator examining FIG. 9 shows the value/phase of the reference signal from the generator. Note that the value/phase of the cos(ft+α), is advanced from the reference signal cos(ft) by the angle α. To acquire the angle α in the PWM/Counter, we need to start counting up when cos(ft+α) has a rising zero crossing as triggered by the modulation path's comparator (206). The STOP signal will occur when the reference comparator (226) has a rising edge zero crossing. Since the position of the STOP signal is substantially consistent and only subject to thermal variations and noise, it is possible to store this STOP value and directly STOP the up-counter digitally rather than using the comparator (206) directly. (It is also possible to average out comparator (226) noise by running and storing multiple STOP acquisitions and storing the average value. The START comparator may also be chopped (for offset cancellation) on a cycle-to-cycle basis to remove systematic offsets. Similarly, the STOP Comparator can be chopped to reduce offset, but this forces the STOP values to be processed in pairs and will halve the update rate. The entire STOP path (DAC plus comparator) may be powered down most of the time, operating at a very low duty cycle, reducing power consumption. For example, if this signal path is active for only one in thirty-two operational cycles, its contribution to overall power consumption becomes negligible. This power saving mode can be combined with other power saving modes described herein. If the STOP circuits (223, 224, 226) are quiescent, the PWM/Counter block (248) only needs to process the START signals. The position (count) of the START signals varies with the magnetic angle α. The offset and delay of the comparator (206) will impact the registered value of START. But, since both comparators (206, 226) experience substantially similar input signal amplitudes and slew rate, they will have similar delays which will cancel each-other out. However, noise and offset may still impact the results.

To address these issues, one or more of the following methods may be utilized. Chopping the comparator (206) on a cycle-by-cycle basis can mitigate offset issues and noise induced jitter can be reduced by averaging multiple START cycles at the cost of a reduction in acquisition speed. This is an unavoidable consequence to any angle acquisition technology since even the raw sensor alone, but also any amplification/comparator stages will contribute to a noisy result. The Differential-to-Single-Ended Amplifiers (202, 212) may have their offsets continuously chopper stabilized since they are processing relatively low frequency content. The comparators (206, 226) process high speed data. Normally this would make offset chopping impractical, but since the comparator offset is only critical at the moments of transition, which are a full acquisition cycle in temporal spacing, there will always be enough time between transitions to switch and chop the input polarity from one cycle to the next. Again, the only penalty is that a pair of two cycles is required to cancel offsets. The averaging of two cycles implicitly adds some angle “smearing” incurred by the speed of the angle rotation (da/dt), which when it is at a high rate, will have some change between the two cycles. This should not have a significant impact on the angle accuracy. Design optimization can address these issues.

FIG. 34 adds and details an incremental mode in which the STOP value is substantially fixed and the START value represents the angle α (the STOP signal is originating from the reference path). This mode allows for substantially reduced latency. Since the analog circuits can be paused and resumed arbitrarily to save power, as long as they are always active during the comparator transitions, that same power reduction method can be modified to set the sine and cosine generators to retrace the values near the last detected zero crossing that resulted in the detection of angle α being represented as an up-down counter value recorded by a START event. The STOP value is stored as shown in FIG. 33. The DAC counter can be reset to a lower count value that corresponds to a time before the last START event (before the zero crossing and at a calculated margin consistent with the filter and circuit settling plus the maximum angular change requirements). This time event is labeled as STARTretraceb in FIG. 39. The bold line in the cos(ft+α) plot in FIG. 39 shows the margining around the last START value labeled as STARTa that allows for the new STOP value to be captured by comparator (206) and uses the α_{retrace} signal “IncrementalMode” to control the PWM/Counter (248). FIG. 11 indicates angle α which is extracted using the standard operating mode, contrasting it against the angle α_{retrace} which is subsequently extracted using the Incremental Mode. Internally programmed parameters would need to be set to govern the update rate, power saving values, and retracing parameters. To enter IncrementalMode, the extraction engine will first have to operate in standard mode and acquire at least one angle solution. Once the angle is acquired, and a START value is stored, the operation in incremental mode is possible. Updating the STOP value to account for temperature drift may require an independent Cosine reference generator. This extra reference signal generator only needs to have a small LUT that is centered around the zero crossing. Making this generator independent allows it to update and average the STOP values independently of all other functions. This has negligible impact on power and area. FIG. 11 shows the timing for the IncrementalMode. The first STARTa and STOPa on the left side deliver an initial angle α. The STOP value is stored in memory (which is invariant with respect to angle α). The Sine and Cosine generators are in sleep mode until the expected position of the next STARTretraceb is approaching. Substantially before the next STARTretraceb, the generators are enabled and retrace the region (shown in a bold line) of the expected START based on the last zero crossing. A new and START called STARTretraceb is stored in the START register labeled as STARTretrace. The stored value of the previous STOPS is used to calculate the new angle α_{retrace}. The START values (varying according to angle α) obtained in the normal operating mode will be no different than the START values obtained in incremental mode, but in incremental mode the START values are obtained by retracing a small fraction of the lookup table, saving power and time. Incremental Mode sacrifices direct PWM operation, but the PWM can be synthesized by the recorded positions of START and STOP and then using a counter that is always active.

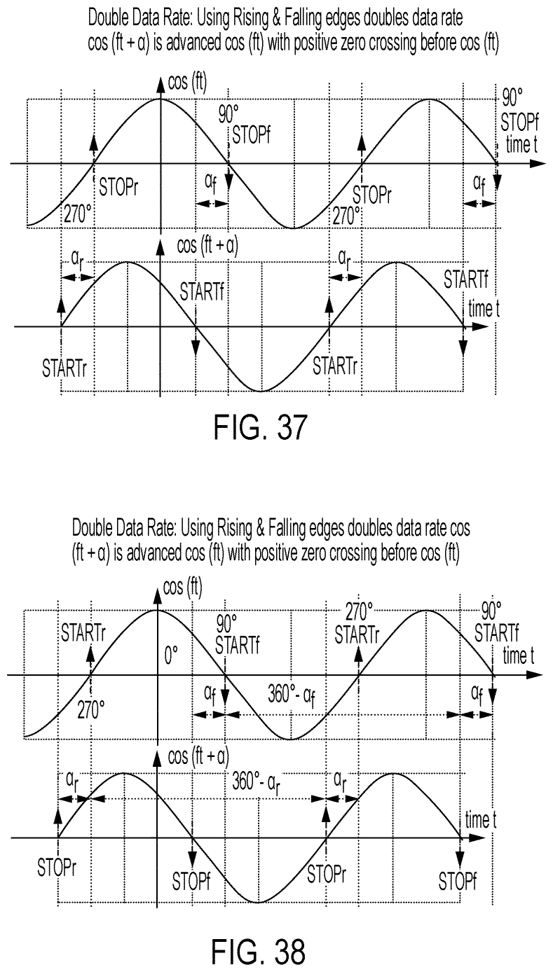

FIG. 35 adds a double data rate operational mode (with the STOP signal originating from the reference path). In this mode, instead of one angle α being acquired per operational cycle in the normal/default cycle mode, two angles are acquired. The '728 architecture only uses the rising edges of the comparator (206,226) outputs to START and STOP the PWM/COUNTER block (238). The equivalent information is available additionally using the falling edges of the same comparators (206,226). This result, using falling edges, will occur a half cycle delayed from the result using rising edges. Using both sets of edges effectively doubles the output rate and halves the latency at the worst-case cost of adding a second copy of the up-counter and stored values of START and STOP in PWM/COUNTER BLOCK (248). The Angle Extraction Engine will produce a digital angle α every half cycle, and there will be two PWMs operating a half cycle apart. If only one PWM is used, then there only needs to be a duplication of the S TART AND STOP registers with some added glue logic to separate/distinguish between rising edges and falling edges from the comparators. Just as was required for the standard rising edge operational mode, the falling edge mode requires a separate calibration to be run and stored on the falling edge STOP signals. Likewise, the results of noise averaging are independently processed and stored. Again, aside from noise and offsets, the falling edges of the two comparators will have substantially similar values and tend to cancel each-other out. A duplication of calibration modes to account for Rising and Falling comparator edges manifests as added control pins to the PWM/Counter (248). There would also be a required duplication of the 4 angle output pins which is not shown (due to space limitations in the diagram). The initial set of output pins (aPWM, StopVal, StartVal, aVal) will be replaced by 4 rising edge related outputs (aPWMr, StopValR, StartValR, aValr) and 4 falling edge related outputs (aPWMf, StopValF, StartValF, aValF). The falling edge START and STOP values will occur temporally 180 degrees delayed from the rising edge values if the angle α is static. FIG. 37 illustrates the timing diagram for the Double Data Rate method illustrated in FIG. 35 when implemented with an up-counter (with the output representing α degrees) whereas FIG. 38 illustrates the timing if the up-counter in FIG. 35 is changed to a down-counter resulting in an output that represents (360−α) degrees

The Relationship Between Clocks and Counters: The main high frequency clock is called the CounterClock or CountClk as shown in FIG. 28. This clock is divided by K to create the DacClk which drives the LUT address register which is a programable up/down counter.

### Relationships between Clocks And Counters With Alternative Extraction Methods

There are two clocks in the system:

High Frequency Angle Incrementing Clock: The high frequency counter clock (CountClk) has a relationship to the angle counter register such that each clock is a fraction of 360 degrees with increments that match the resolution specification of the system. Thus, an angle counter with 12 bits has 4096 counts. This means that 1 count of the angle counter represents an increment of 0.088 degrees (360/4096). The actual clock speed depends on the requirement speed to resolve an angle. For instance, if an angle solution must be delivered within 8 us, then the 12-bit counter must fully cycle every 8 us and the high frequency counter clock speed is 1.95 ns (1/(8 us*4096).

Low Frequency Sequence Clock: There is also a Sequence Clock labeled DacClk. This clock is used to address the LUTs for the Sine and Cosine Generators. It is usually much slower than the CountClk. This is due to the limited size of the LUTs. The DacClk is expressed as a factor of K slower than the CountClk. If the system is configured to generate only 256 points per cycle for the sine and cosine generators, then the required DacClk would be a 31.2 ns clock (8 us/256). The ratio K between the clocks would be 16.

Arrange the Sequence-Counter Such that the Rising zero crossing of the cos ft signal coincides with the ZERO Count: Depending on the order of the time indexed (time axis) values in the LUTs, the LUT can be arranged such that the zero count of the Sequence-Counter register for the cos ft generator coincides with the rising edge zero crossing of the digitally generated cos ft in FIG. 30. (Here, the actual rising zero crossing of the cos ft wave as shown in FIG. 9 is delayed by the RC filter and the comparator propagation response time.

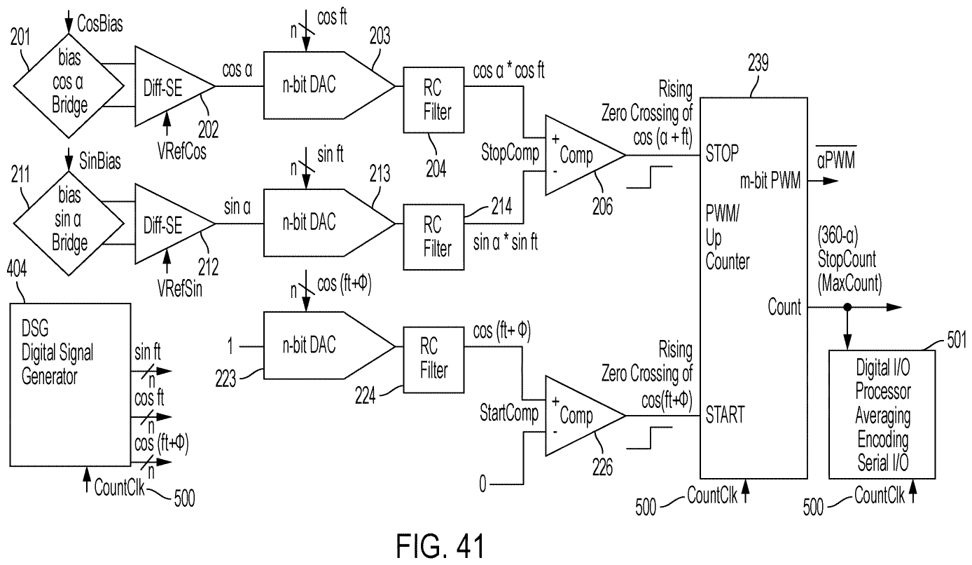

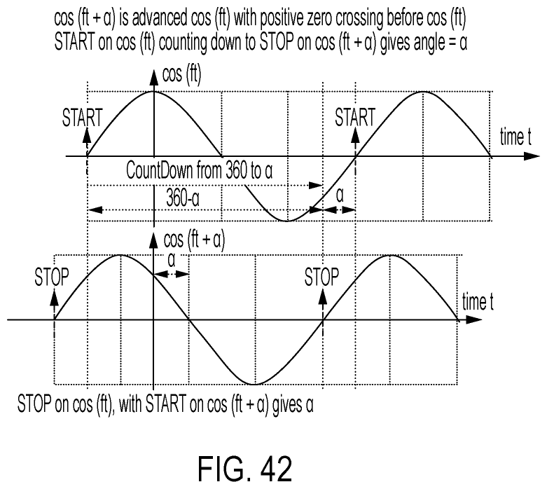

Countdown Method Using Rising Edge of cos ft as START and Rising Edge of cos(ft+α) as the STOP: If the rising zero crossing of the analog output of cos(ft) is used as a START signal for the PWM/Counter in FIG. 41 and if the rising zero crossing of the analog output of cos(ft+α) is used as the STOP signal, we can set the PWM/Counter to full count on the START and count down with every CountClk's clock pulse. This is accomplished by changing the Up Counter in FIG. 41 to a Down-Counter. Since full scale is the same as zero scale (0 deg=360 deg), the counter will count down to the value of the angle α which occurs when the STOP pulse is received. The waveform timing for this mode is shown in FIG. 42. This method does not require any specific relationship between the PWM/Counter and the Sequence-Counter, but using this method as a basis method will allow for virtualized STARTs and STOPs to be implemented which can be used to improve noise immunity and reject comparator offsets from the analog system.

Countdown Method Using Virtual STARTs: If the ZERO count of the Sequence-Counter is arranged to be “just before” the START in FIG. 42, then it can be assumed that all STARTS will appear at substantially the same delay after the Sequence-Counter ZERO. Comparator offsets will impact this delay as will thermal changes that affect the comparator's propagation delay. If the AngleDownCounter (AKA DownCounter, the PWM/Counter used in a count-down mode) is initialized at zero scale value (0 deg=360 deg) at the ZERO of the Sequence-Counter and the DownCounter is allowed to count down continuously, then the START edge may be used to store a count-value of the DownCounter which is non-zero and labeled DownCount (START). Subsequently, when the STOP edge occurs, the value of the DownCounter is Stored and labeled DownCount (STOP). The difference between these virtual STARTs and STOPs represents the angle α. Since the value of the START should be substantially identical from one cycle to the next, a more accurate START value may be mathematically improved by averaging a number of START values. The more values that are averaged, the less noise effects the calculated angle α. Additionally, the START comparator may be chopped to eliminate input offsets if the averages used to virtualize the START are always taken from an even number of values. The STOP values can be similarly averaged, but if a is changing with time, these values cannot be used. However, as long as the angle α is static, then it can be averaged. In this mode, the START and STOP comparators only need to be enabled when they are expected to produce an edge, saving power. Generally, the STOP comparator is enabled once per cycle since α may be a dynamic quantity, but the START comparator only needs to be enabled for enough cycles to accumulate a noise immune average. Then it can be disabled for many cycles and only be reenabled to track slow temperature changes. The fact that the START typically occurs a few counts after the initial ZERO value of the DownCounter, implies that for some angles of α, near α=0, the down counter will have crossed zero (because the START and STOP were not confined to a single counting cycle of the DownCounter. For these cases, the angle α will be determined using the START count value, the STOP count value and an overflow bit value.

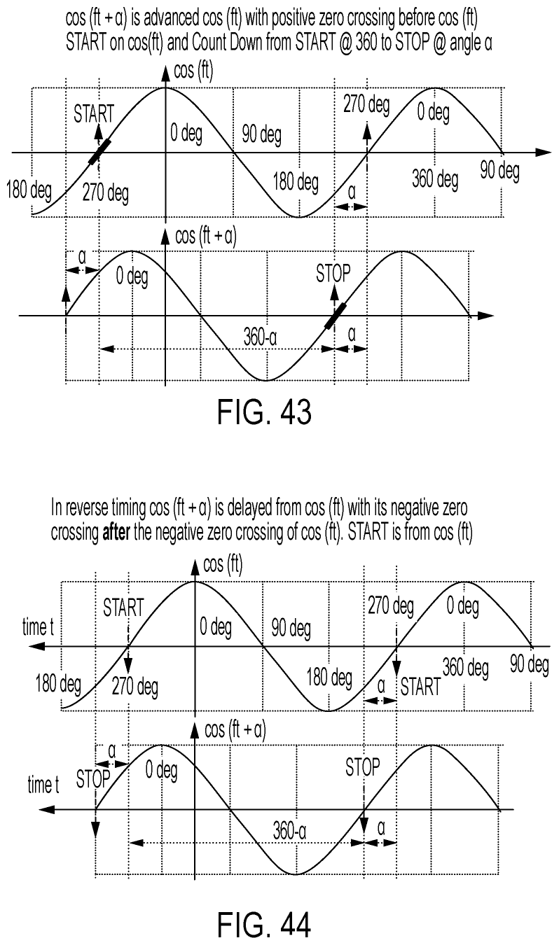

Incremental Update Method using the Countdown Method with Virtual STARTs: Using the above method for a basis, the virtual STARTs are used as above, but instead of having a continuous Sequence-Counter and a continuous DownCounter, these two counters are only active near the START events and the STOP events. Moreover, both counters are disabled between STARTs and STOPs after the first angle acquisition and only activated near the ZERO count to occasionally update the STOP register. Once this is accomplished, the counters may be forced to be near the value of the last STOP event, retracting the STOP value with some margin. This provides a much more frequent angle update than the baseline operation in which only one angle value is produced per operational cycle. This is an example of the waveform timing for this mode is shown in FIG. 43. The latency in this mode approaches zero. The only negative consequence of operating in this incremental mode is that the more frequent the updates occur, the higher power consumption is required.

Reverse Sequence Method using the Count-up: Taking the waveform diagram in FIG. 42 and reversing the time axis to simulate running all the sequence counters in reverse, the START signal is taken from the falling zero crossing of the reverse timed cos(ft) comparator and the STOP signal is taken from the reverse timed cos(ft+α). This is illustrated in FIG. 44.

There are many equivalent methods of configuring the system: swapping STARTs AND STOPS, counting up or down, using rising vs falling edges, running the generators counting down to effectively reverse the generators in time, counting to α, counting to 360−α.

Using the above configuration, the angle α is delivered when the counter stops and the timing of the START to the STOP may be used to form the PWM, but the PWM would need to be inverted if the time of the logically HI state is used to represent the angle α. The PWM is effective in this mode because the START and STOP delays are substantially the same and thus cancel out, imposing a small delay on the PWM output. Since the PWM is effectively a time averaging output this delay is not substantial.

This same configuration can be used with virtual starts and stops to improve accuracy by suppressing comparator noise through averaging of either STARTs or STOPs. Averaging STARTs will have no impact on angle acquisition time, but averaging STOPs forces the angle acquisition time to span many cycles since an average of many cycles is required to suppress STOP noise/jitter.

There are some architectural modifications required in the PWM/Counter block to implement a virtual START. The PWM counter needs an additional bit: for example, the 12-bit counter is augmented to a 13-bit counter. This is required because the PWM/Counter is initiated at ZERO in this configuration and starts counting down when the generator's Sequence-Counter is at ZERO. The START pulse will always be delayed by several counts of the PWM/Counter due to delays in the analog signal path.

### Modes of Operation

POWER SAVING: A thoughtful examination of the system behavior leads to the realization that the all the analog blocks (Bridges (201, 211), Amplifiers (202, 212), DACs (203, 213, 223), Signal Generators (301, 312, 333) can be put in a standby mode when the comparators are sufficiently spaced in time from their zero crossings. Thus, immediately after a comparator detects a zero crossing, producing a START or STOP event, all analog circuits may be put in a low power mode. The analog circuits must wake up substantially before the next zero crossing occurs. The only requirement is that by the time the next zero crossing occurs, the analog circuits have settled and most importantly, the RC filters have settled. Predicting when this turn-on will be required is straight forward: the up-down counter value on the last zero crossing corresponding to angle α can be stored and used to trigger the resumption of the full power state by adding a margin that accounts for settling times and a possible change in angle due to rotation of the magnetic field. The enabling and disabling of the circuits in the reference cosine path is always consistent and independent of the magnetic angle α.

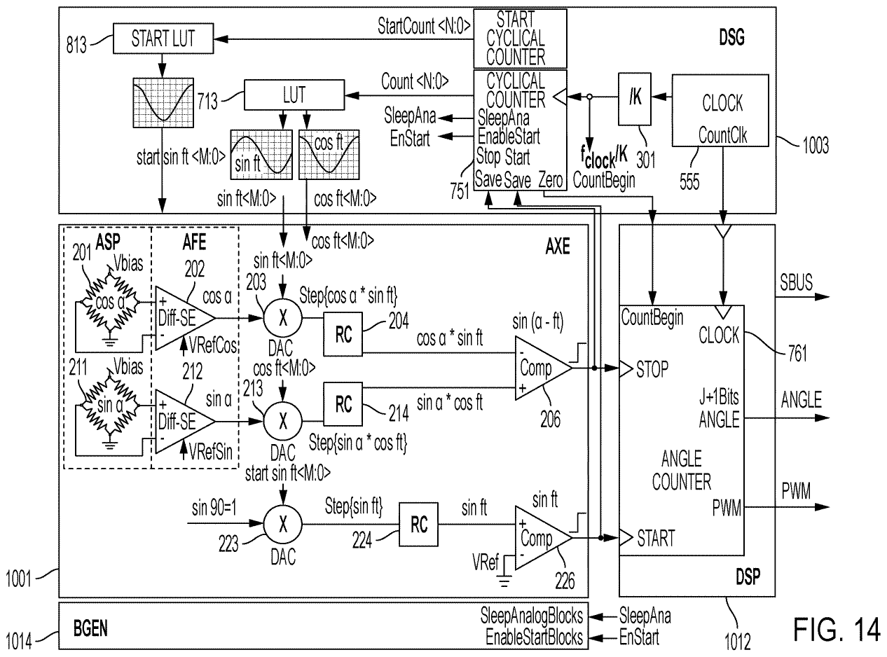

POWER SAVING MODES: FIG. 12, FIG. 13 and FIG. 14 support in-depth examination of the system behavior that leads to the realization that the all the analog blocks (Bridges (201,211), Amplifiers (202,212), DACs (203,213, 223), Signal Generators (301,312,333) can be put in a standby mode when the comparators are sufficiently spaced in time from their zero crossings. Thus, immediately after a comparator detects a zero crossing, producing a START or STOP event, all analog circuits may be put in a low power mode. The analog circuits must wake up substantially before the next zero crossing occurs. The only requirement is that by the time the next zero crossing occurs, the analog circuits have settled and most importantly, the RC filters have settled. Predicting when the circuits need to become active is straight forward: the up-down counter value on the last zero crossing corresponding to angle α can be stored and used to trigger the resumption of the full power state by adding a margin that accounts for settling times plus a possible change in angle due to rotation of the magnetic field. The enabling and disabling of the circuits in the reference cosine path is always consistent and independent of the magnetic angle α. Thus, powering down the reference path is a consistent and predictable procedure. FIG. 40 indicates temporal regions in which the reference path and the signal paths need to be enabled to detect the zero crossings. At all other times, it is possible to disable the analog measurement circuits.

INCREMENTAL UPDATE MODE: Since the analog circuits can be paused and resumed arbitrarily to save power, that same method can be modified to set the sine and cosine generators to retrace the values near the last zero crossing that resulted in angle α being represented as an up-down counter value. The counter can be reset to a lower count value before the zero crossing (at a calculated margin consistent with the settling plus maximum angular change requirements) and subsequently obtain an angle update in a small fraction of the full time compared to a free running acquisition cycle. This mode will potentially consume more power than the low power modes that are possible when running at the “single data rate” or the “double data rate” modes since the comparators will be active for a higher percentage of a cycle if they are providing data updates at a much higher rate than one output angle per cycle.

A listing of operational modes follows:

BASIC MODE: The STARTs and STOPs of the PWM/Counter are directly triggered by the rising edges of the Start Comparator (206) and the Stop Comparator (226).

LOW OFFSET MODE: Same operation as basic mode, but both comparators are chopped between cycles such that the offsets are flipped between cycles yielding a net zero offset if two cycles are averaged.

VIRTUAL STOP MODE 1: The stop comparator is chopped between cycles, and an average value is accumulated of multiple cycles, eliminating offset and reducing noise. The STOP value is stored in a register and no longer taken directly from the rising edge of the stop comparator (226). The START value is directly taken from the un-chopped Start Comparator (206) producing a near constant offset in the angle result, which can be calibrated out at several temperature values.

VIRTUAL STOP MODE 2: The same as VIRTUAL STOP MODE 1, but the Start Comparator (206) is chopped between cycles. This produces an offset jitter in the angle detection as seen by a jumping forward and back in the PWM output due to the alternation of offset in the Start Comparator (206). The offset can be cancelled in the raw output angle updates if the angle update happens every two cycles, allowing for the averaging of a pair of START values to cancel offset.

DOUBLE DATA RATE: The published version of this system only uses the rising edges of the comparator (206, 226) outputs to START and STOP the PWM/COUNTER block (238). The equivalent information is available using the falling edges of the same comparators (206, 226). This result using falling edges would be a half cycle delayed from the result using rising edges. Using both sets of edges effectively doubles the output rate at the worst-case cost of adding a second copy of the PWM/COUNTER BLOCK. Each half cycle will produce a digital angle α and there will be two PWMs operating a half cycle apart, but the total PWM time for each output is still a full cycle. The latency has been cut in half. If only one PWM is used, then there only needs to be a duplication of the START AND STOP registers with some added glue logic to separate/distinguish between rising edges and falling edges from the comparators.

DOUBLE DATA RATE MODE 1: Similar to BASIC MODE, but both the rising and falling edges of the Start and Stop comparators are used to obtain two angle results per cycle, one result from the falling edges and an additional result from the rising edges. There are two possible PWM outputs that are 180 degrees apart.

DOUBLE DATA RATE with VIRTUAL STOP MODE 2: Similar to VIRTUAL STOP MODE 1 both the rising and falling STOP values are chopped and averaged and stored in a RisingStop and FallingStop register. The rising and falling STARTS are taken directly from the Start Comparator (206). As in MODE 1, there are two possible PWM outputs that are 180 degrees apart. All outputs PWM and raw angle will have a systematic jitter due to the chopping of the Start Comparator (206).

DOUBLE DATA RATE with VIRTUAL STOPs and STARTs that are averaged by pairs of cycles MODE 3: Each sequential pair of rising START edges and falling START edges is averaged to cancel offset. The STOP is virtual as in MODE 2. An offset cancelled result is available every two cycles for both the rising and falling edges. By staggering the averages, each cycle will produce a result, one from the falling edge and one from the rising edge. They will be staggered by 180 degrees due to the spacing between rising and falling comparator edges. This staggering may be pipelined to space the updates 360 degrees apart.

LOW POWER MODE applied to any of the above modes: Comparators only need to be active during an active edge transition. Thus, all comparators may be immediately powered down after an edge transition and then powered up in advance of the next expected edge. The advance margin depends on filter settling time for filters (204, 214, 224) with an additional margin for the change in angle due to the impact of the next angle's position due to rotation speed and direction.

INCREMENTAL MODE 1 rising edge mode: The stop comparator (226) is only enabled near the expected zero crossings. The values are stored in a STOP Register. Pairs of rising and falling edge STOPs are averaged and stored over multiple cycles with the chopping alternated between each rising falling pair. The result is stored to produce a virtual STOP stored in a register. The results are updated frequently enough to capture timing changes due to thermal changes. The rising START value is captured during the first operational cycle, and then that value is stored and the Start Comparator (226) is disabled immediately after the rising edge. The value of the START is used to determine a margin around that value which allows for a change in angle αnd settling of the filters (204, 214). That value is used to reset the PWM/counter to a value incrementally before the last recorded transition and the comparator (206) is enabled until a new rising edge from the comparator (206) is detected. This cycle is repeated at a programmable frequency. Very short latencies are possible. The main cost of frequent partial updates are tolerable if improved resolution is required. Between each partial cycle the offset of the Start Comparator is chopped. Averaging each pair averages out the offset of the comparator via chopping.

INCREMENTAL MODE 2 falling edge mode: This mode is identical to MODE 1, but it uses the falling edges of the comparator (206).

INCREMENTAL MODE 3 rising and falling edge mode: This mode uses both rising and falling edges of the comparator (206). A pair of chopped results using the rising edge and a pair chopped results using the falling edge are alternated.

DIFFERENTIAL ARCHITECTURE: All of the above-described architectures and modes may be implemented using an Analog Front End (AFE) that is pure differential until the comparator outputs. Thus, in FIG. 3, FIG. 4, FIG. 6, FIG. 7, FIG. 3, and FIG. 8, Blocks 202, 212, 203, 213, 223, 204, 214, 224 are fully differential. The comparator blocks (206, 226) have differential inputs but have single-ended outputs. Likewise, in FIG. 4 the Data lines between blocks 303 to 203, 313 to 213, and 323 to 223 are digital differential, and in FIG. 5, the Data lines from block 333 to blocks 203,213, and 223 are digital differential. In the single-ended implementation the digital values in the LUT have a zero-value representing the most negative value of the sinusoidal waveform, while the maximum digital value represents the most positive value of the sinusoid. The zero crossings of the sinusoids occur at half scale. In the differential mode implementation, the sinusoids are represented by a complementary pair of digital numbers with the zero crossings having both outputs at midscale and the most positive value of the sinusoid has the first digital output at full scale while the second digital output is at zero. Similarly, the most negative value of the sinusoid has the first output at zero while the second output is at full scale. This differential mode eliminates the need for a zero-scale input to the Stop Comparator (226). It also eliminates the need for a differential to single-ended conversion in amplifiers 202 and 212 which can be a source of error. Differential architecture also eliminates the unity reference on the DAC block 223 with a digital pair of numbers in which the first number represents full-scale while the second number represents 0-scale.

DSP Mode for Precision Static Angles: All of the above-described architectures and modes may use DSP to post-process the angle data. If the angle is nearly constant, this state may be detected by setting a tolerance window around the current angle measurement buffer of multiple angle measurements is maintained and averaged. If the angle variations conform within the specified window, the average angle data may then be presented with an effective improvement in precision because of noise reduction and an effective increase in bit-depth because of over-sampling. Over-sampling effectively allows an interpolation that increases bit-depth. The precision using this averaging mode is improved and noise is averaged out. The size of the averaging buffer may be selected by registers. The transition to this mode is automatic and a return to normal non-averaged mode is automatic if the tolerance window is exceeded. This mode is only activated if a one-bit register is set.

DSP Mode for Precision Constant Velocity: All of the above-described architectures and modes may use DSP to post process the angles for operation where the angular velocity is near constant. The change in angle between two angle readings is monitored. If the change in angle is nearly constant as specified by a tolerance window register, for a specified number of samples. In this mode the angle updates are projected in time such that the latency is virtually zero. This mode is only activated if a one-bit register is set.

Bi-Directional Operation: All of the above-described architectures are compatible with signals that can operate either in clockwise and counter-clockwise rotations of both directions. Unlike some other angle measurement devices, there are no directional restrictions.

Multiple Sensors: When operating in an Incremental Angle Mode, a Power Saving Mode, and either of these modes using virtual stops and starts, the comparators and the sinusoidal generators may be powered down for a majority of a cycle. Likewise, in these modes the input amplifiers would also be powered down. It is possible to insert an analog multiplexor between the sensors and the DACs. This multiplexor can have a multiplicity of inputs that are used to support the connection of a multiplicity of internal and external sensors. Thus, a single IC containing the angle extraction machine containing only one AFE/AXE may support a multiplicity of either internal or external sensors which are time multiplexed. Powering the stages down between switching inputs is not required. If powering-down is not utilized, it is also possible to mask out the comparator outputs during switching transients. If this masking is implemented, it is possible that all operation modes can be used with multiple sensors. If calibration is utilized, different calibration values are stored for each sensor and its corresponding analog signal path.

Multiple Sensors with Buffering: If many sensors are multiplexed, it may be necessary to buffer each sensor with a dedicated Differential-to-Single-Ended input amplifier to prevent crosstalk and loss of speed due to parasitic wiring.

Integrated and Off-Chip Sensors: Sensors may be located externally/off chip, on-chip as part of the process of a single IC or integrated into the chip level package.

Calibration: Calibration improves accuracy. Calibration of all the signal paths may be done at a multiplicity of range of angles. This calibration involves fine tuning of amplifier gain stages and may also trim out offset and offset induced errors. The value of the RC filters may be tuned for both delay matching across the 3 filters and optionally tuning for temperature variations might be required. (Small matched and tracking RC variations might not impact performance. Uneven delay and response times across channel may be optionally tuned to match, reducing improving precision. Calibration values may be stored in OTP (One Time Programmable), MTP (Multiple Time Programmable) or FTP (Few Time Programmable) Memories that are either on or off chip. Calibration is also used to calibrate the effects of applications where the spinning magnet is off-axis and not concentrically aligned with the sensors' centers. In the case of calibration for off axis effects, it is likely that this particular data is stored off-chip and loaded from an external memory via a data bus. Other calibrated values may be stored on-chip because the calibration is only required for the IC itself, but when calibrating the off-axis behavior, this is a function of the embedded systems geometry and alignment and not due to internal error contributions.

Sensor Bias: Raw sensors configured as a Wheatstone Bridge with 4 terminals as shown in FIG. 1. Typically, the bottom of the bridge is connected to ground, and the top of the bridge is biased with a current source. Alternatively, the top of the bridge may be a fixed supply, and the bottom of the bridge connects to a current source. The 2 middle taps are the differential output signals containing analog angle data. To support external bridges, four extra wires are required for each bridge to manage power consumption and kelvin the ground connection. A bias current is required to bias the bridge. This current might be a fixed value, but using a variable current might be used to compensate for temperature variations. The bridge bias may either be a current source or a voltage source.

Sensor Output Voltage Compensation: It is desirable that the analog signal swing at the inputs of the Sine and Cosine DACs (203, 213) are matched and calibrated to a fixed full-scale value when the angle α is 90 degrees for the sine DAC and the angle α is 0 degrees for the cosine DAC. This mismatch is partially due to resistive variations between the sine and cosine bridges. One method to compensate the signal amplitude is to vary the gains of the Differential-to-Single-Ended Amplifiers (202,203), the equivalent may be accomplished by varying the amplitude of the current biasing the sine bridge (201) and the cosine bridge (211). Likewise, adjusting the signal sizes as temperature varies may be accomplished by adjusting either the amplifier gains or the bridge bias currents. These thermal adjustments may be implemented using a LUT for measured temperature vs amplifier gain, or an analog signal that is temperature dependent. These methods may be applied to either the amplifier gain or the bridge bias, but the bridge bias modulation over temperature is a simpler scheme. Likewise scaling the bridge bias to control signal size is one implementation that can be used. The bridge bias may either be a voltage source or a current source.

Interpreting the Angle Register: Generally, the angle register is a copy of the final value of the PWM/Counter in each operating cycle. This counter is initialized to a value of zero at the time of the START signal and counts up (or down). It contains a final count at the time of the STOP signal which represents the angle α of the magnetic field. For example, during a complete cycle of either the sine or cosine generators, this clock would count up to a full value (a 12 bit counter has a full value of 4096); at the time of the STOP signal, the counter's value represents the angle α as a percentage of 360 degrees (for a 12 bit counter, the angle α is the count, divided by 4096 multiplied by 360 degrees: 360*COUNT/FULL_COUNT degrees); thus one result angle α is produced per counting cycle.

It is also possible to use the START and STOP edges of the comparators to produce a PWM whose pulse width is proportional to the angle α, where the pulse width divided by the full cycle time gives the angle α: α=360*PULSE_WIDTH/CYCLE_TIME degrees.

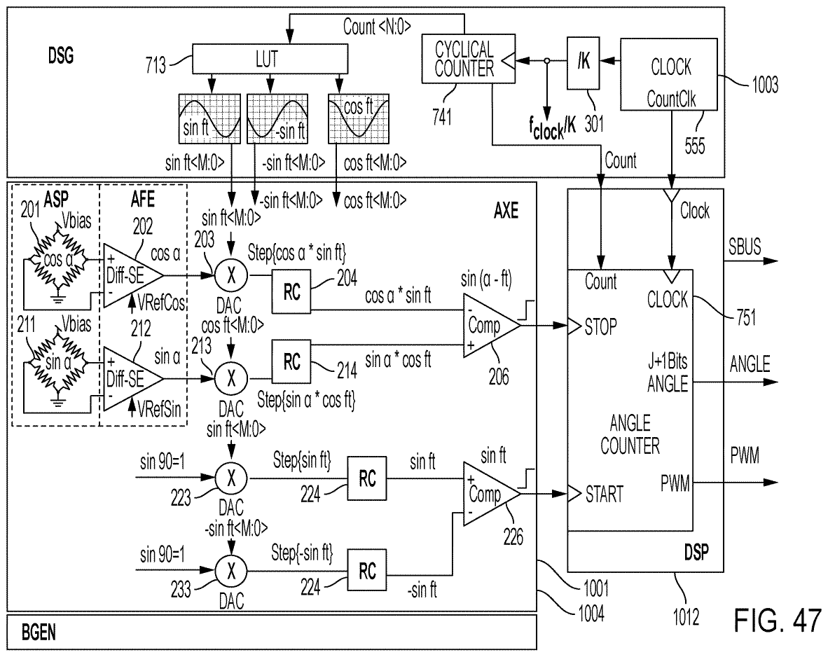

Finally, FIG. 47 is a modification of Figure in which the reference signal to the START comparator is replaced with a signal originating from an inverted sine wave (−sin(ft)).

What is claimed is:

1. A circuit for measuring the angle αnd the angular velocity of a magnetic field imposed upon a pair of magnetic sensors, comprising:
a first electronic circuit comprising:
a first multiplying digital to analog converter (DAC) having a first reference input, a first digital input receiving a first waveform at a substantially higher frequency (f) than a rotational frequency of the magnetic field, and a first DAC output,
a first programmable gain differential to single-ended amplifier having a first input connected to receive a first electronic signal from a first magnetic sensor, and a first amplifier output connected to the first reference input, and
wherein the first electronic circuit provides a first electronic output based on the first DAC output;
a second electronic circuit comprising:
a second multiplying digital to analog converter (DAC) having a second reference input, a second digital input receiving a second waveform at the frequency (f), and a second DAC output,
a second programmable gain differential to single-ended amplifier having a second input connected to receive a second electronic signal from a second magnetic sensor, and a second amplifier output connected to the second reference input, and
wherein the second electronic circuit provides a second electronic output based on the second DAC output;
a first zero-crossing detection circuit comprising a first comparator having an input connected to receive a signal based on the first DAC output, and configured to compare the signal based on the first DAC signal to a reference signal to produce a first zero-crossing signal having an edge when the first DAC output crosses the reference signal;
a second zero-crossing detection circuit comprising a second comparator, having a substantially similar delay as the first comparator, connected to receive a first signal based on the first DAC output and a second signal based on the second DAC output, and configured to compare the first signal to the second signal to produce a second zero-crossing signal having an edge when the first signal and second signal cross;
a digital counter, clocked by a clock signal having a clock frequency greater than the frequency (f), and having a first input connected to receive the first zero-crossing signal and a second input connected to receive the second zero-crossing signal, the digital counter configured to start and stop counting based on the first zero-crossing signal and the second zero-crossing signal, the digital counter having a counter output indicative of a measurement of an angle of an external magnetic field imposed upon the sensors.

2. The circuit of claim 1, wherein the measurement of the angle comprises a value indicative of the angle or a complement of the angle according to a trigonometric function selected from the group comprising:
sin α*cos ft−cos α*sin ft=sin(α−ft),
cos α*cos ft−sin α*sin ft=cos(α+ft),
cos α*sin ft−sin α*cos ft=sin(α−a),
cos α*cos ft−sin α*sin ft=cos(α−a),
sin α*cos ft+cos α*sin ft=sin(α+ft), or
cos α*cos ft+sin α*sin ft=cos(α−ft).

3. The circuit of claim 1, wherein the reference signal comprises a fixed reference signal.

4. The circuit of claim 1, wherein the reference signal comprises an inverse of the signal based on the first DAC signal.

5. The circuit of claim 1, further comprising:
a first first-order filter connected to receive the first DAC output to produce the signal based on the first DAC output; and
a second first-order filter connected to receive the second DAC output to produce the signal based on the second DAC output.

6. The circuit of claim 5, further comprising a digital waveform generator configured to generate the first waveform and the second waveform.

7. The circuit of claim 1, wherein the first and second multiplying digital to analog converters are configured to operate one only in a temporal vicinity of zero crossings.

8. The circuit of claim 1, wherein the digital counter operates in a count-up mode.

9. The circuit of claim 1, wherein the digital counter operates in a count-down mode.

10. The circuit of claim 1, wherein the circuit is configured to operate in an incremental mode wherein temporal sections of the first waveform and the second waveform not in a temporal vicinity of zero crossings are eliminated.

11. The circuit of claim 1, wherein the circuit is configured to disable analog signal paths when the sections of the first and second waveforms are not in the temporal vicinity of zero crossings.

12. The circuit of claim 1, wherein the circuit is configured to repetitively trace through the counter values near the last count value.

13. The circuit of claim 1, wherein the first waveform and the second waveform are trigonometric waveforms.

14. The circuit of claim 1, wherein the first comparator and the second comparator are chopper stabilized.

15. The circuit of claim 1, wherein the first comparator and the second comparator are chopper stabilized with chopping toggling on alternate angle acquisition cycles.

16. The circuit of claim 1, wherein the first differential amplifier and the second differential amplifier are chopper stabilized.

17. A circuit for measuring the angle αnd the angular velocity of a magnetic field, comprising:
a first magnetic sensor at a first physical location at a first fixed orientation such that the first magnetic sensor generates a first electronic signal representing a sine of an angle (α) of the magnetic field;
a second magnetic sensor at a second physical location in proximity to the first physical location and having a second fixed orientation orthogonal to the first fixed orientation such that the second magnetic sensor generates a second electronic signal representing a cosine of the angle of the magnetic field;
a first electronic circuit comprising:
a first multiplying digital to analog converter (DAC) having a first reference input, a first digital input receiving a first waveform at a substantially higher frequency (f) than a rotational frequency of the magnetic field, and a first DAC output,
a first programmable gain differential to single-ended amplifier having a first input connected to receive the first electronic signal and a first amplifier output connected to the first reference input, and
wherein the first electronic circuit provides a first electronic output based on the first DAC output;
a second electronic circuit comprising:
a second multiplying digital to analog converter (DAC) having a second reference input, a second digital input receiving a second waveform at the frequency (f), and a second DAC output,
a second programmable gain differential to single-ended amplifier having a second input connected to receive the second electronic signal and a second amplifier output connected to the second reference input, and
wherein the second electronic circuit provides a second electronic output based on the second DAC output;
a first zero-crossing detection circuit comprising a first comparator having an input connected to receive a signal based on the first DAC output, and configured to compare the signal based on the first DAC signal to a reference signal to produce a first zero-crossing signal having an edge when the first DAC output crosses the reference signal;
a second zero-crossing detection circuit comprising a second comparator, having a substantially similar delay as the first comparator, connected to receive a first signal based on the first DAC output and a second signal based on the second DAC output, and configured to compare the first signal to the second signal to produce a second zero-crossing signal having an edge when the first signal and second signal cross;
a digital counter, clocked by a clock signal having a clock frequency greater than the frequency (f), and having a first input connected to receive the first zero-crossing signal and a second input connected to receive the second zero-crossing signal, the digital counter configured to start and stop counting based on the first zero-crossing signal and the second zero-crossing signal, the digital counter having a counter output indicative of a measurement of an angle of an external magnetic field imposed upon the sensors.

18. A circuit for measuring the angle αnd the angular velocity of a magnetic field, comprising:
means for multiplying a first electrical signal based on an output of a first magnetic sensor with a first waveform at a substantially higher frequency (f) than a rotational frequency of the magnetic field to provide a first output;
means for multiplying a second electrical signal based on an output of a second magnetic sensor with a second waveform at the frequency (f) to provide a second output;
a first zero-crossing detection circuit comprising a first comparator having an input connected to receive a signal based on the first output, and configured to compare the signal based on the first signal to a reference signal to produce a first zero-crossing signal having an edge when the first output crosses the reference signal;
a second zero-crossing detection circuit comprising a second comparator, having a substantially similar delay as the first comparator, connected to receive a first signal based on the first output and a second signal based on the second output, and configured to compare the first signal to the second signal to produce a second zero-crossing signal having an edge when the first signal and second signal cross;
a digital counter, clocked by a clock signal having a clock frequency greater than the frequency (f), and having a first input connected to receive the first zero-crossing signal and a second input connected to receive the second zero-crossing signal, the digital counter configured to start and stop counting based on the first zero-crossing signal and the second zero-crossing signal, the digital counter having a counter output indicative of a measurement of an angle of an external magnetic field imposed upon the sensors.
